(19) United States
(12) Patent Application Publication
(10) Pub. No.: US 2025/0385180 A1
(43) Pub. Date: Dec. 18, 2025

(54) THREE-DIMENSIONAL MEMORY DEVICES AND METHODS FOR FORMING THE SAME

(71) Applicant: YANGTZE MEMORY TECHNOLOGIES CO., LTD., Wuhan (CN)

(72) Inventors: Yang Chen, Wuhan (CN); Zhong Zhang, Wuhan (CN); Kun Zhang, Wuhan (CN); Di Wang, Wuhan (CN); Wenxi Zhou, Wuhan (CN)

(21) Appl. No.: 18/761,604

(22) Filed: Jul. 2, 2024

Related U.S. Application Data
(63) Continuation of application No. PCT/CN2024/099259, filed on Jun. 14, 2024.

(51) Int. Cl. H01L 23/528; G11C 16/04; H10B 41/10; H10B 41/27; H10B 41/35; H10B 41/41; H10B 43/10; H10B 43/27; H10B 43/35; H10B 43/40

(52) U.S. Cl. CPC H01L 23/5283; G11C 16/0483; H01L 23/528; H10B 41/10; H10B 41/27; H10B 41/35; H10B 41/41; H10B 43/10; H10B 43/27; H10B 43/35; H10B 43/40

(57) ABSTRACT

In certain aspects, a memory device is provided. The memory device includes a stack structure and a contact structure. The stack structure includes a first stack structure including interleaved first dielectric layers and second dielectric layers, and a second stack structure including interleaved first dielectric layers and conductive layers. The contact structure includes a contact member extending, in a first direction, through the first stack structure and includes an interconnect member extending in a second direction perpendicular to the first direction to connect with a first conductive layer extended from the second stack structure. The interconnect member is arranged at an end of the contact member and connected with the contact member. In the first direction, a thickness of the interconnect member is greater than a thickness of the first conductive layer extended from the second stack structure.

### CROSS-REFERENCE TO RELATED APPLICATIONS

This application is a continuation of International Application No. PCT/CN2024/099259, filed on Jun. 14, 2024, which is hereby incorporated by reference in its entirety.

### BACKGROUND

The present disclosure relates to three-dimensional (3D) memory devices and fabrication methods thereof.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A 3D memory architecture can address the density limitation in planar memory cells. The 3D memory architecture may include memory array and peripheral devices for controlling signals to and from the memory array.

### SUMMARY

In one aspect, a memory device is provided. The memory device may include a stack structure and a contact structure. The stack structure may include a first stack structure including interleaved first dielectric layers and second dielectric layers, and a second stack structure including interleaved first dielectric layers and conductive layers. The contact structure may include a contact member extending, in a first direction, through the first stack structure and may include an interconnect member extending in a second direction perpendicular to the first direction to connect with a first conductive layer extended from the second stack structure. The interconnect member may be arranged at an end of the contact member and connected with the contact member. In the first direction, a thickness of the interconnect member may be greater than a thickness of the first conductive layer extended from the second stack structure.

In some implementations, a difference between the thickness of the interconnect member and the thickness of the first conductive layer may be in a range of 2 nm to 6 nm.

In some implementations, a step may be arranged between a top surface of the interconnect member and a top surface of the first conductive layer; and a thickness of the step may be in a range of 1 nm to 3 nm.

In some implementations, a ratio of the thickness of the first conductive layer to the thickness of the interconnect member may be about 0.4 to about 0.85.

In some implementations, a first interface may be arranged between the interconnect member and the first conductive layer, and a second interface may be arranged between a second dielectric layer of the first stack structure and a second conductive layer of the second stack structure. The second conductive layer may be arranged above the first conductive layer, and a first dielectric layer of the second stack structure may be arranged between the first conductive layer and the second conductive layer in the first direction. In a cross-sectional view of the contact structure, in the second direction, a first distance from a sidewall of the contact member to the first interface may be less than a second distance from the sidewall of the contact member to the second interface.

In some implementations, in the cross-sectional view, in the second direction, the first distance may be less than a third distance between the first interface and the second interface.

In some implementations, the first conductive layer may include a first conductive material, and the interconnect member may include a second conductive material coated with a glue layer. At the first interface, the glue layer may be sandwiched between the second conductive material of the interconnect member and the first conductive material. In some implementations, the glue layer may include Ti/TiN layers.

In some implementations, the second conductive layer may include a first conductive material coated with a high dielectric constant (high-k) gate dielectric layer; and at the second interface, the high-k gate dielectric layer may be sandwiched between the first conductive material of the second conductive layer and the second dielectric layer.

In some implementations, the first conductive layer may include a first conductive material covered with a high-k gate dielectric layer at top and bottom surfaces of the first conductive layer; the interconnect member may include a second conductive material coated with a glue layer at sidewalls of the interconnect member; and the glue layer may be sandwiched between the first conductive material and the second conductive material.

In some implementations, the first conductive material may be identical to the second conductive material.

In some implementations, each of the first conductive material and the second conductive material may include at least one of tungsten or titanium nitride.

In some implementations, the first conductive material may be different from the second conductive material.

In some implementations, the first conductive material may include tungsten, and the second conductive material may include titanium nitride.

In some implementations, an interface may be arranged between the interconnect member and the first conductive layer; and a top surface of the glue layer of the interconnect member may be in contact with a first dielectric layer of the first stack structure.

In some implementations, the memory device may include channel structures extending through part of the second stack structure in the first direction; and in a cross-sectional view of the contact structure, each of the conductive layers, other than the first conductive layer, may extend laterally to a region adjacent to the contact structure to be connected with a corresponding second dielectric layer of the first stack structure through which the contact structure extends.

In some implementations, the memory device may include dummy channel structures extending through part of the second stack structure, the part of the second stack structure being adjacent to the first stack structure through which the contact structure extends.

In some implementations, the interconnect member may be sandwiched between two first dielectric layers of the first stack structure in the first direction.

In some implementations, the contact member may include: a contact spacer over a sidewall of the contact member; a contact material over the contact spacer; and a contact filler surrounded by the contact material.

In some implementations, the contact filler may include a polysilicon layer.

In some implementations, the memory device may include slit structures each extending through the second stack structure in the first direction and laterally extending in a third direction, the third direction perpendicular to the first direction.

In some implementations, two slit structures of the slit structures may be discontinuous and aligned in the third direction; the first stack structure through which the contact structure extends may be a first dielectric stack structure; and the memory device may further include an isolation structure arranged between the two slit structures. The isolation structure may extend through a second dielectric stack structure in the first direction. The second dielectric stack structure may include an interleaved structure of the first dielectric layers and third dielectric layers, the third dielectric layers being different from the second dielectric layers.

In another aspect, a system is provided. The system may include a memory device and a memory controller coupled to the memory device and configured to control an operation of the memory device. The memory device may include a stack structure and a contact structure. The stack structure may include a first stack structure including interleaved first dielectric layers and second dielectric layers, and a second stack structure including interleaved first dielectric layers and conductive layers. The contact structure may include a contact member extending, in a first direction, through the first stack structure and may include an interconnect member extending in a second direction perpendicular to the first direction to connect with a first conductive layer extended from the second stack structure. The interconnect member may be arranged at an end of the contact member and connected with the contact member. In the first direction, a thickness of the interconnect member may be greater than a thickness of the first conductive layer extended from the second stack structure.

In still another aspect, a method of forming a semiconductor structure of a memory device is provided. The method may include forming a stack structure including a first stack structure that includes interleaved first dielectric layers and second dielectric layers, and a second stack structure that includes interleaved first dielectric layers and conductive layers; and forming a contact structure including a contact member extending, in a first direction, through the first stack structure and including an interconnect member extending in a second direction perpendicular to the first direction to connect with a first conductive layer extended from the second stack structure. The interconnect member is arranged at an end of the contact member and connected with the contact member; and in the first direction, a thickness of the interconnect member is greater than a thickness of the first conductive layer extended from the second stack structure.

In some implementations, forming the stack structure includes forming the first stack structure including the interleaved first dielectric layers and second dielectric layers and arranged in a first region and a second region of the semiconductor structure, respectively; forming the contact structure includes forming a sacrificial contact structure extending, in the first direction, through the first stack structure in the second region; forming the stack structure further includes replacing the second dielectric layers of part of the first stack structure with the conductive layers to form the second stack structure, in the first region and second region, including an interleaved structure of the first dielectric layers and the conductive layers; and forming the contact structure further includes forming the contact structure based on the sacrificial contact structure, wherein the bottom of the contact structure extends in the second direction perpendicular to the first direction to connect with the first conductive layer extended from the second stack structure in the second region.

In some implementations, forming the sacrificial contact structure in the second region includes: forming a first portion of the sacrificial contact structure extending, in the first portion, through the first stack structure in the second region; forming a second portion of the sacrificial contact structure connected with the first portion of the sacrificial contact structure and extending laterally perpendicular to the first direction; and forming a third portion of the sacrificial contact structure extended from the second portion, a thickness of the second portion, in the first direction, being greater than a thickness of the third portion, and the second portion including a first material different from a second material of the third portion.

In some implementations, forming the contact structure based on the sacrificial contact structure may include replacing the second material of the third portion, through a slit opening, with one or more conductive materials of the first conductive layer; and replacing the first material of the second portion, through a contact hole, with a contact material.

In some implementations, forming the sacrificial contact structure extending through the first stack structure in the second region includes: forming a contact hole extending, in the first direction, through the first stack structure in the second region; forming a first lateral recess at a bottom of the contact hole, the first lateral recess corresponding to a second dielectric layer of the first stack structure and corresponding to a top first dielectric layer and a bottom first dielectric layer, neighboring the second dielectric layer, of the first stack structure; removing the corresponding second dielectric layer from the first lateral recess to form an extended lateral recess; forming a first liner layer in the extended lateral recess; and forming a second liner layer in the first lateral recess, the first liner layer being different from the second liner layer, and in the first direction.

In some implementations, in the first direction, a thickness of the extended lateral recess may be less than a thickness of the first lateral recess.

In some implementations, the first liner layer may include a polysilicon layer.

In some implementations, the second liner layer may include a silicon nitride layer.

In some implementations, the method may further include forming channel structures extending through the first stack structure in the first region and dummy channel structures extending through the first stack structure in the second region. Forming the second stack structure including the interleaved structure of the first dielectric layers and the conductive layers, may include replacing the second dielectric layers of the first stack structure, corresponding to the channel structures, in the first region and replacing the second dielectric layers of the first stack structure, corresponding to the dummy channel structures, in the second region, with the conductive layers, respectively, to form the second stack structure in the first region and in the second region.

In some implementations, replacing the second dielectric layers of the first stack structure, corresponding to the channel structures, in the first region and replacing the second dielectric layers of the first stack structure, corresponding to the dummy channel structures, in the second region with the conductive layers, respectively, may include through a second slit opening, replacing the second dielectric layers of the first stack structure, corresponding to the dummy channel structures, in the second region and replacing the first liner layer in the extended lateral recess, with third liner layers, respectively; through a first slit opening, removing the second dielectric layers of the first stack structure, corresponding to the channel structures, in the first region to form first replacement recesses; removing the third liner layers in the extended lateral recess and in the second region to form second replacement recesses, the second replacement recesses including the extended lateral recess; and forming the conductive layers in the first replacement recesses of the first region and the second replacement recesses of the second region, the first conductive layer including one or more conductive materials and being arranged in the extended lateral recess.

In some implementations, each of the third liner layers may include a carbon layer.

In some implementations, the method may include forming a first sacrificial filling structure in the first region and a second sacrificial filling structure in the second region, respectively; removing a second filling material in the second sacrificial filling structure to form the second slit opening in the second region; and removing a first filling material in the first sacrificial filling structure to form the first slit opening in the first region.

In some implementations, the method may further include after forming the second stack structure in the first region and in the second region, filling the first slit opening and the second slit opening with one or more slit filling materials to form a first slit structure in the first region and a second slit structure in the second region.

In some implementations, the first slit structure in the first region and the second slit structure in the second region may be discontinuous.

In some implementations, the method may further include before forming the one or more conductive materials in the first replacement recesses and in the second replacement recesses, forming a high-k dielectric layer in each of the first replacement recesses and the second replacement recesses.

In some implementations, each of the conductive layers, other than the first conductive layer, may be in contact with a corresponding second dielectric layer of a remaining first stack structure in the second region.

In some implementations, a high-k gate dielectric layer may be arranged between one or more conductive materials of a conductive layer of the second stack structure and a remaining second dielectric layer in the second region.

In some implementations, a high-k gate dielectric layer may be arranged between one or more conductive materials of the first conductive layer in the extended lateral recess and the second liner layer in the first lateral recess.

In some implementations, forming the contact structure based on the sacrificial contact structure may include: removing the second liner layer in the first lateral recess to expose the high-k gate dielectric layer; removing the high-k gate dielectric layer to expose the one or more conductive materials of the first conductive layer in the extended lateral recess; and forming a contact material coated with a glue layer in the first lateral recess, the glue layer being in contact with the one or more conductive materials of the first conductive layer.

In some implementations, the method may further include forming a contact pad on the contact structure to connect with the contact material of the contact structure.

In some implementations, the semiconductor structure may be a first semiconductor structure; and the method may further include bonding the first semiconductor structure with a second semiconductor structure on which peripheral circuits are formed.

In some implementations, forming the first stack structure may include forming the first stack structure over a substrate. The method may further include: forming channel structures extending through the second stack structure in the first region of the first semiconductor structure; upon the first semiconductor structure being bonded with the second semiconductor structure, removing, from a side of the first semiconductor, the substrate and part of a memory film in each channel structure to expose a semiconductor channel of each channel structure; and forming a semiconductor layer to connect the semiconductor channel of each channel structure.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1A illustrates a plan view of a 3D memory device having contact structures, according to some aspects of the present disclosure.

FIG. 1B illustrates various cross-sectional side views of a 3D memory device having contact structures, according to some aspects of the present disclosure.

FIG. 1C illustrates a plan view of another 3D memory device having contact structures, according to some aspects of the present disclosure.

FIG. 1D illustrates a plan view of still another 3D memory device having contact structures, according to some aspects of the present disclosure.

FIG. 2 illustrates a flowchart of a method for forming a 3D memory device having contact structures, according to some aspects of the present disclosure.

FIGS. 3A-3U illustrate fabrication processes for forming a 3D memory device having contact structures, according to some aspects of the present disclosure.

FIG. 4 illustrates a flowchart of a method for forming a sacrificial contact structure, according to some aspects of the present disclosure.

FIG. 5A is an enlarged cross-sectional view showing a contact hole and lateral recesses, according to some aspects of the present disclosure.

FIG. 5B is an enlarged cross-sectional view showing a contact structure, according to some aspects of the present disclosure.

FIGS. 6A-6D illustrate fabrication processes for replacing second dielectric layers, according to some aspects of the present disclosure.

FIG. 7 illustrates a block diagram of an exemplary memory device having bonded semiconductor structures, according to some aspects of the present disclosure.

FIG. 8 illustrates a block diagram of an exemplary system having a 3D memory device, according to some aspects of the present disclosure.

FIG. 9A illustrates a diagram of an exemplary memory card having a 3D memory device, according to some aspects of the present disclosure.

FIG. 9B illustrates a diagram of an exemplary solid-state drive (SSD) having a 3D memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “some implementations,” “exemplary implementations,” “other implementations,” “some examples,” etc., indicate that the implementation described may include a particular feature, structure, or characteristic, but every implementation may not necessarily include the particular feature, structure, or characteristic. Moreover, such phrases do not necessarily refer to the same implementation. Further, when a particular feature, structure or characteristic is described in connection with an implementation, it would be within the knowledge of a person skilled in the pertinent art to effect such feature, structure, or characteristic in connection with other implementations whether or not explicitly described.

In general, terminology may be understood at least in part from usage in context. For instance, the term “one or more” as used herein, depending at least in part upon context, may be used to describe any feature, structure, or characteristic in a singular sense or may be used to describe combinations of features, structures, or characteristics in a plural sense. Similarly, terms, such as “a,” “an,” or “the,” again, may be understood to convey a singular usage or to convey a plural usage, depending at least in part upon context. In addition, the terms “based on” and “according to” may be understood as not necessarily intended to convey an exclusive set of factors and may, instead, allow for the existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Furthermore, a layer can be a region of a homogeneous or inhomogeneous continuous structure that has a thickness less than the thickness of the continuous structure. For instance, a layer can be located between any pair of horizontal planes between, or at, a top surface and a bottom surface of the continuous structure. A layer can extend laterally, vertically, and/or along a tapered surface. A substrate can be a layer, can include one or more layers therein, and/or can have one or more layers thereupon, thereabove, and/or therebelow. A layer can include multiple layers. For instance, an interconnect layer can include one or more conductor and contact layers (in which interconnect lines and/or vertical interconnect access ‘VIA’ contacts are formed) and one or more dielectric layers.

As used herein, the terms “nominal/nominally” and “substantial/substantially” refer to a desired, or target, value of a characteristic or parameter for a component or a process operation, set during the design phase of a product or a process, together with a range of values above and/or below the desired value. The range of values can be due to slight variations in manufacturing processes or tolerances. As used herein, the terms “about” and “approximately” indicate the value of a given quantity that can vary based on a particular technology node associated with the subject semiconductor device. Based on the particular technology node, the terms “about” and “approximately” can indicate a value of a given quantity that varies within, for example, 10-30% of the value (e.g., ±10%, ±20%, or ±30% of the value).

As used herein, the term “3D memory device” may refer to a semiconductor device with vertically oriented strings of memory cell transistors (referred to herein as “memory strings,” such as NAND memory strings) on a laterally-oriented substrate so that the memory strings extend in the vertical direction with respect to the substrate. As used herein, the term “vertical/vertically” means nominally perpendicular to the lateral surface of a substrate.

With the development of three-dimensional (3D) memory technology, there are growing demands for both cost reduction and performance improvement of a 3D memory device. As the number of layers within the stack structure continues to increase, various fabrication processes for 3D memory devices may have emerged. In other examples, to address the cost concerns, it also becomes imperative to identify possibilities for streamlining and merging certain stages of these processes.

A 3D memory structure may include a substrate and a stack structure formed over the substrate. The stack structure may include a first stack structure, corresponding to a core array region where a plurality of memory cells are configured for data storage, and an adjacent second stack structure in a connection region between the core array region and a peripheral region. The first stack structure may include interleaved first dielectric layers and conductive layers, while the second stack structure may include interleaved first dielectric layers and second dielectric layers. A contact structure, extending through the second stack structure in the connection region, can be formed and may be configured to couple with one of the conductive layers extended from the first stack structure. In this manner, the conductive layer can function as a word line, while the contact structure can serve as a word line pick-up structure.

To form the 3D memory device, a stack structure initially having interleaved first dielectric layers, and second dielectric layers can be formed in both the core array region and the connection region. Subsequently, a gate replacement process can be performed to replace the second dielectric layers of part of the stack structure with the conductive layers. In some examples, high dielectric constant (high-k) gate dielectric layers can be formed prior to the formation of the conductive layers, such that the conductive layers can be surrounded by the high-k gate dielectric layers. Subsequently, a contact structure can be formed.

To form the contact structure configured to bring the connection with the conductive layer, the high-k gate dielectric layer surrounding the conductive layer can be removed to expose the conductive layer. A conductive material may later be deposited into a contact opening to form part of the contact structure and establish the connection with the conductive layer. Due to issues such as high-k material losses, however, the connection interface between the contact structure and the conductive layer may be discontinuously formed, thus resulting in a weak point in signal communication paths. Moreover, the losses in the high-k material can potentially promote a reaction between the conductive material of the conductive layer and the residual dielectric layers, consequently leading to a stress leakage issue. In the present disclosure, multiple contact structures may be formed in the processes, configured to connect with multiple conductive layers at different depths. The severity of these issues may increase, particularly when a contact structure having a greater depth is formed.

To mitigate one or more of the aforementioned issues, the present disclosure introduces certain solutions in which one or more liner layers can be formed in a sacrificial contact structure to function as stop layers before the gate replacement process. By the introduction of the liner layers, the connection interface between the contact structure and the conductive layer can be arranged closer to the contact structure, thus being relocated away from the signal communication paths. Consequently, these approaches can effectively tackle the stress leakage issues and further circumvent the challenges associated with thinning, e.g., silicon nitride layers and silicon oxide layers of the stack structure (a.k.a., an “NO” stack).

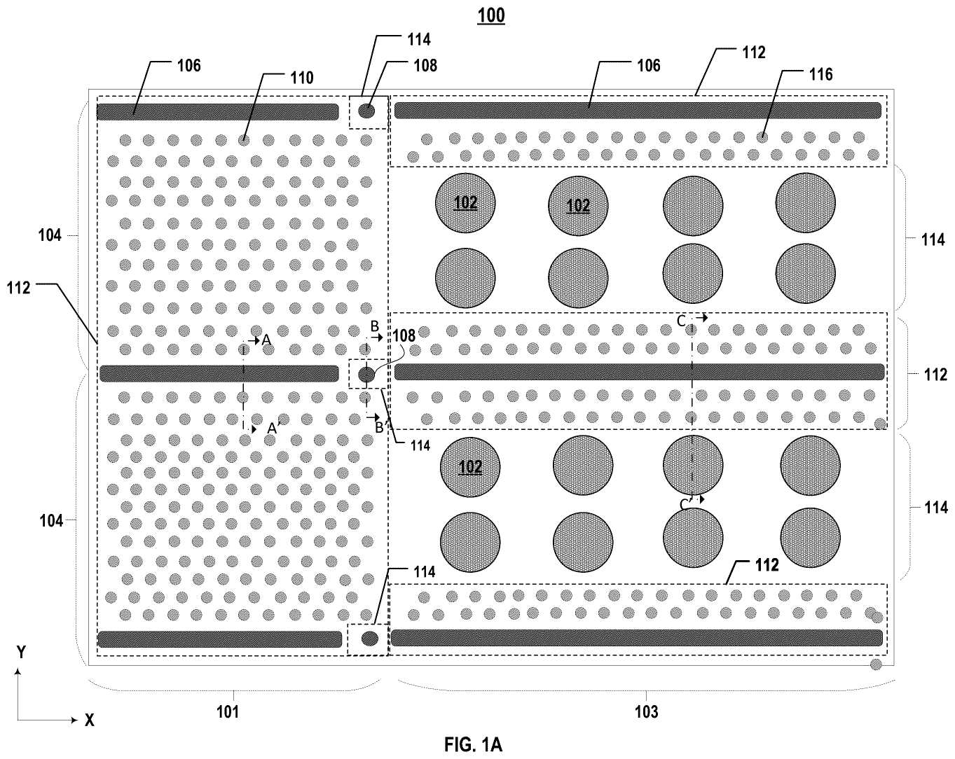

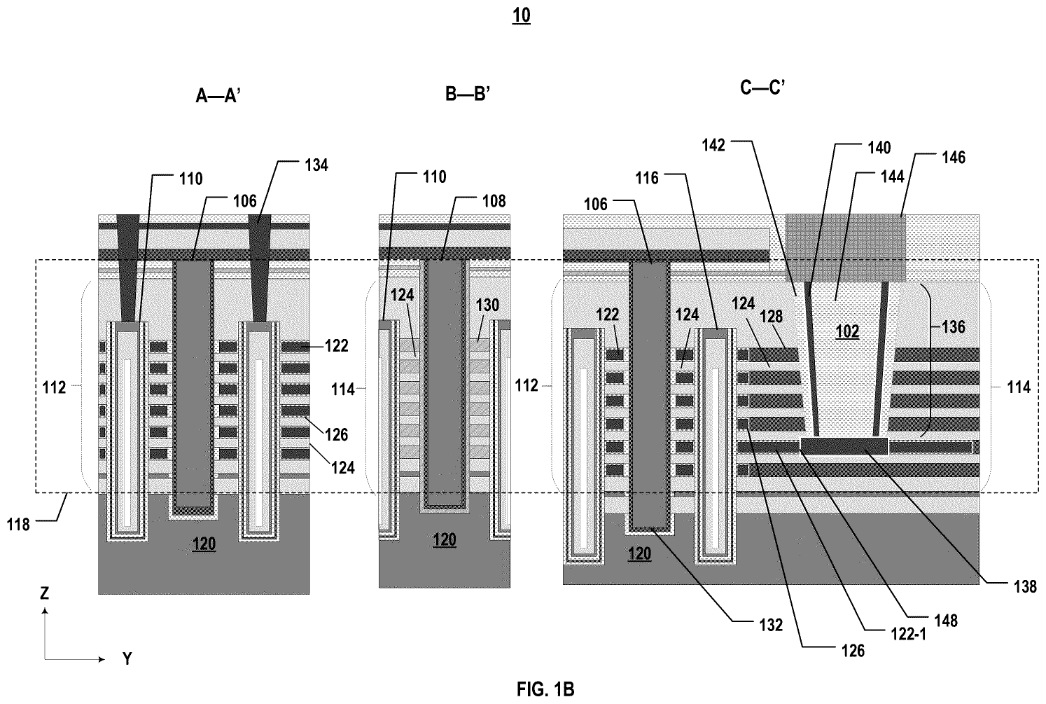

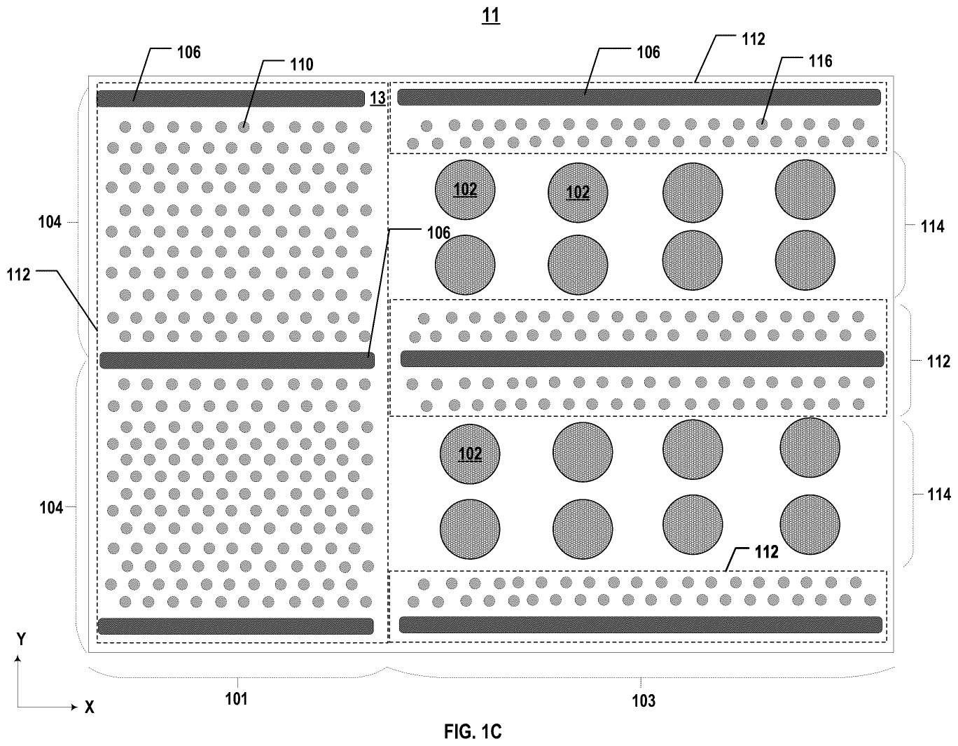

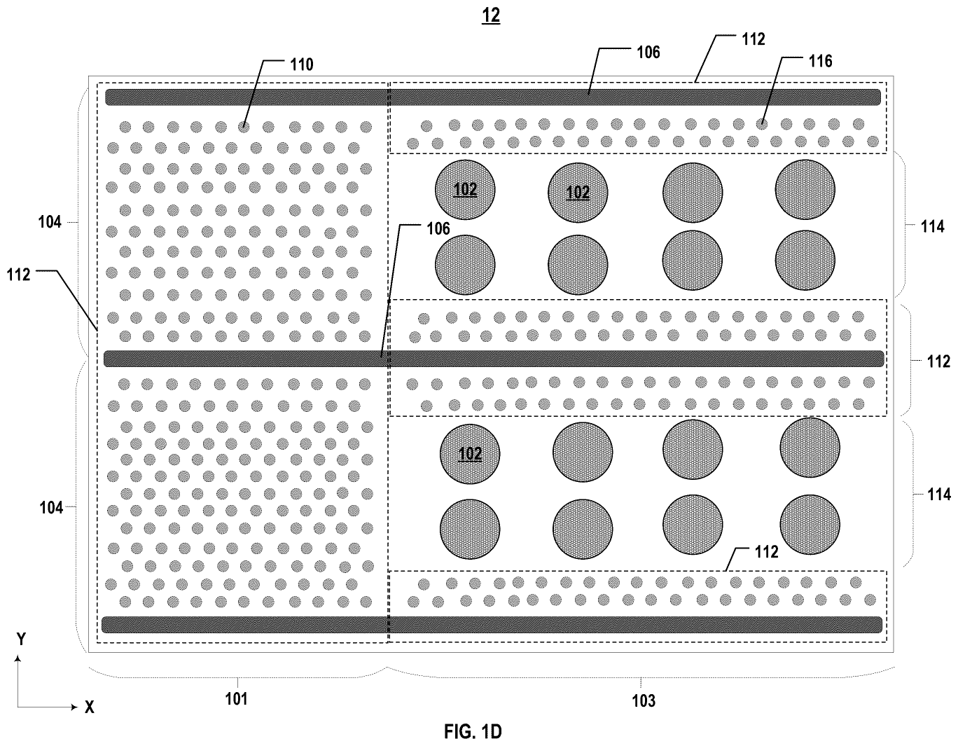

FIG. 1A illustrates a plan view of a 3D memory device 100 having contact structures 102, according to some aspects of the present disclosure. FIG. 1B illustrates various cross-sectional side views of a 3D memory device 10 having contact structures 102, according to some aspects of the present disclosure. It is apparent that 3D memory device 10 in FIG. 1B can be an exemplary implementation of 3D memory device 100 of FIG. 1A. In some implementations, 3D memory device 100 may be a NAND Flash memory device in which memory cells are provided in the form of an array of NAND memory strings. It is noted that x and y axes are included in FIG. 1A to illustrate two orthogonal (perpendicular) directions in the wafer plane. The x-direction may correspond to the word line direction of 3D memory device 100, and the y-direction may correspond to the bit line direction of 3D memory device 100.

According to some implementations, 3D memory device 100 can include one or more blocks 104 arranged in the y-direction (i.e., the bit line direction) separated by parallel separation structures, such as gate line slits (GLSs). In some implementations in which 3D memory device 100 is a NAND Flash memory device, each block 104 may be the smallest erasable unit of the NAND Flash memory device. In some implementations, each GLS may be separated by one or more cuts and may include discontinuous slit structures 106, as shown in FIG. 1A. Slit structures 106 may be aligned along the x-direction (the word line direction). In some examples, an isolation structure 108 may be formed between two slit structures 106 aligned in the x-direction, as shown in FIG. 1A.

FIG. 1C illustrates a plan view of another 3D memory device 11 having contact structures 102, according to some aspects of the present disclosure, while FIG. 1D illustrates a plan view of still another 3D memory device 12 having contact structures 102, according to some aspects of the present disclosure. As shown in FIG. 1C, in some implementations, two aligned slit structures 106 may be simply separated by a cut 13, and no isolation structure is to be arranged between aligned slit structures 106. In other examples, a continuous slit structure 106 extending in the x-direction (i.e., the word line direction) may be formed, as shown in FIG. 1D. The present disclosure does not place limitations thereto. In some implementations, each block 104 in FIGS. 1A, 1C, and 1D can be further divided into multiple fingers (not shown).

Turning to FIG. 1A, 3D memory device 100 can include a core array region 101 in which an array of channel structures 110 are formed, and a connection region 103 (serving as a word line pick-up region) in which contact structures 102 are formed. Array of channel structures 110 in core array region 101 may be configured to store data. Core array region 101 and connection region 103 may be arranged in the x-direction (the word line direction), according to some implementations. It is understood that although one core array region 101 and one connection region 103 are illustrated in FIG. 1A, 1C, or 1D, multiple core array regions 101 and/or multiple connection regions 103 may be included in 3D memory device 100, for example, one connection region 103 between two core array regions 101 in the x-direction, in other examples. It is also understood that FIG. 1A, 1C, or 1D only illustrates portions of core array region 101 that are adjacent to connection region 103.

3D memory device 100 may include a stack structure that includes a conductive stack structure 112 and a dielectric stack structure 114. In some implementations, conductive stack structure 112 may be arranged in core array region 101 and extend laterally to part of connection region 103, as shown in FIGS. 1A, 1C, and 1D. Another part of connection region 103 may include dielectric stack structure 114 arranged between conductive stack structure 112 in the y-direction.

Channel structures 110 in core array region 101 may extend, in the z-direction (i.e., a thickness direction), through conductive stack structure 112 in core array region 101, while contact structure 102 may extend, in the z-direction, through dielectric stack structure 114 in connection region 103. In some implementations, dummy channel structures 116 may be disposed in connection region 103 to provide mechanical support and/or load balancing. Dummy channel structures 116 may extend, in the z-direction, through conductive stack structure 112 in connection region 103. In some implementations, although not shown, dummy channel structures 116 may also extend through dielectric stack structure 114, for example, between contact structures 102 in the x-direction (not shown).

In some implementations, dielectric stack structure 114 may also be arranged in core array region 101. As shown in FIG. 1A, isolation structure 108 may be arranged between two aligned slit structures 106. According to some implementations, isolation structure 108 may extend, in the z-direction, through dielectric stack structure 114 in an intermediate region between core array region 101 and connection region 103. It can be understood that the intermediate region between core array region 101 and connection region 103 may not be strictly defined. It can be simply recognized as a region between core array region 101 and connection region 103. That is, isolation structures 108 can be viewed as being located in core array region 101 or connection region 103, instead.

As shown in FIG. 1A, each block 104 includes two rows of contact structures 102 in connection region 103, and each contact structure 102 may include a circular-sectional shape. It is understood, however, that FIG. 1A only provides an exemplary illustration, rather than being given as a limitation. In other examples, less or more rows of contact structures 102 may be arranged in connection region 103. For instance, four rows of contact structures 102 may be arranged in each block 104. It is also apparent that the layout and arrangement of contact structures 102, as well as the sectional configuration of each contact structure 102, may vary in different examples.

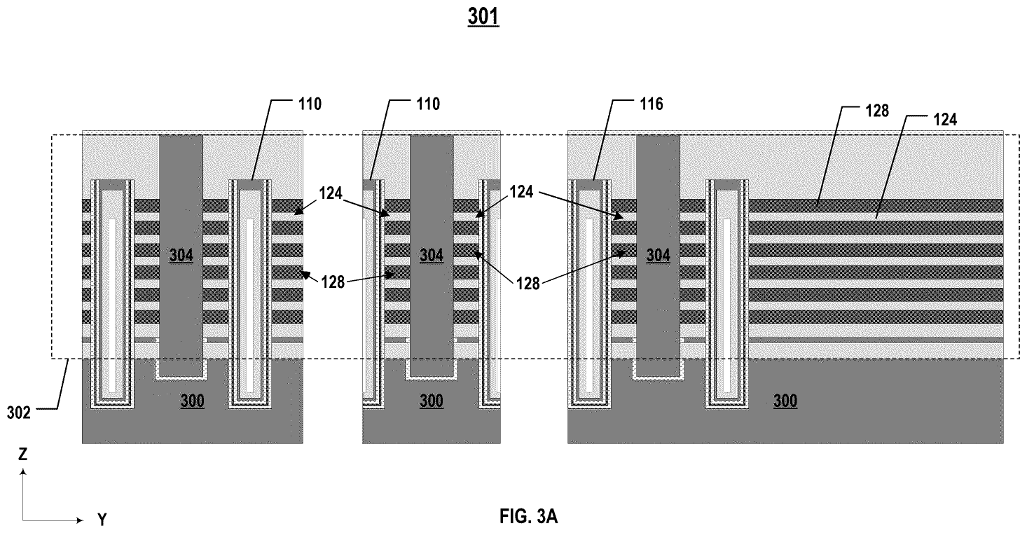

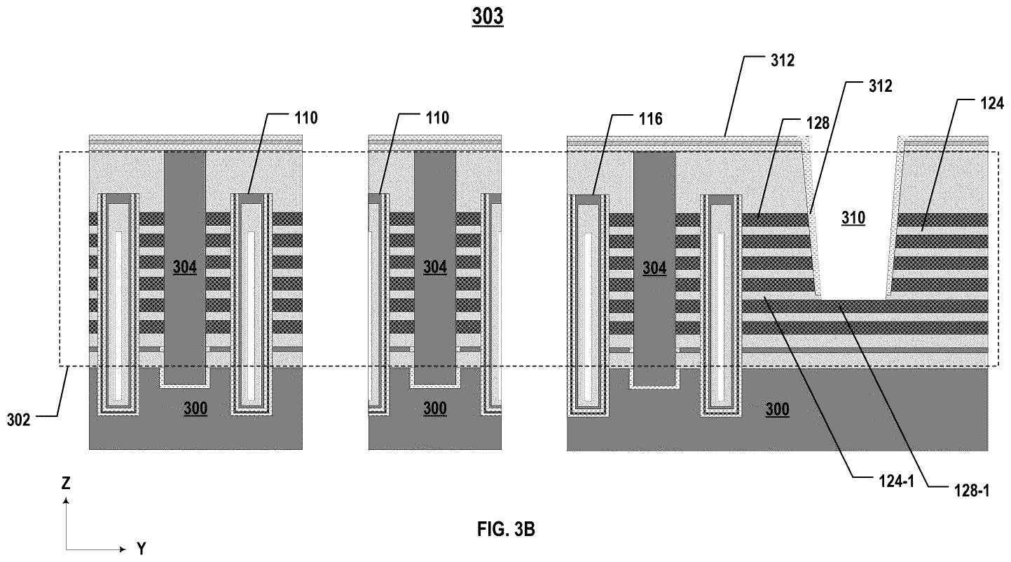

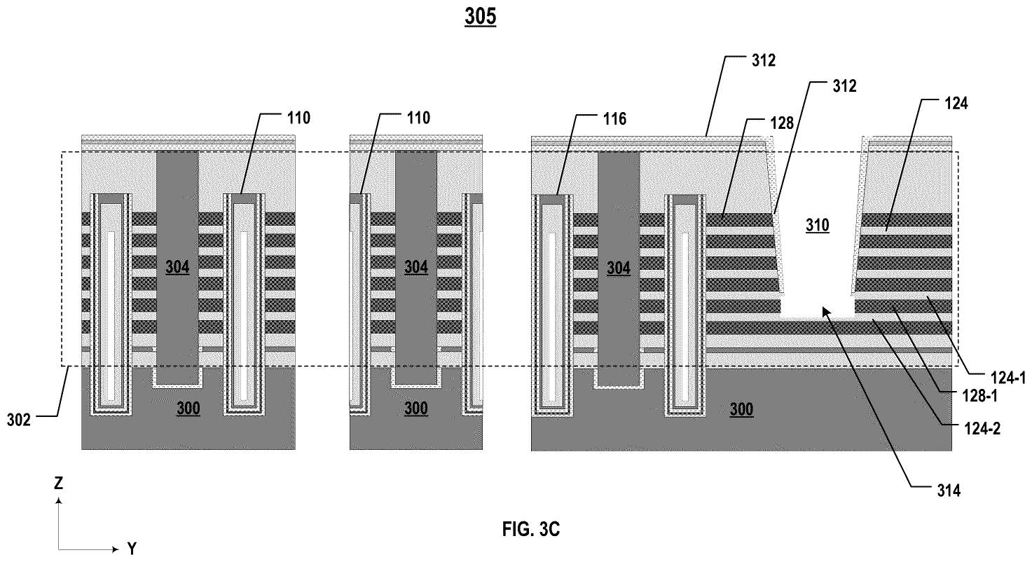

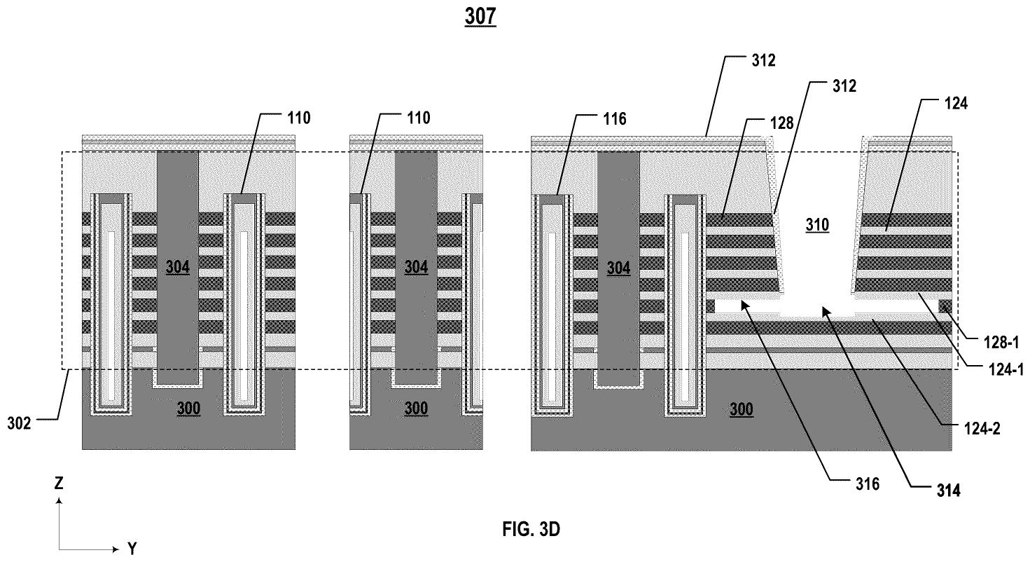

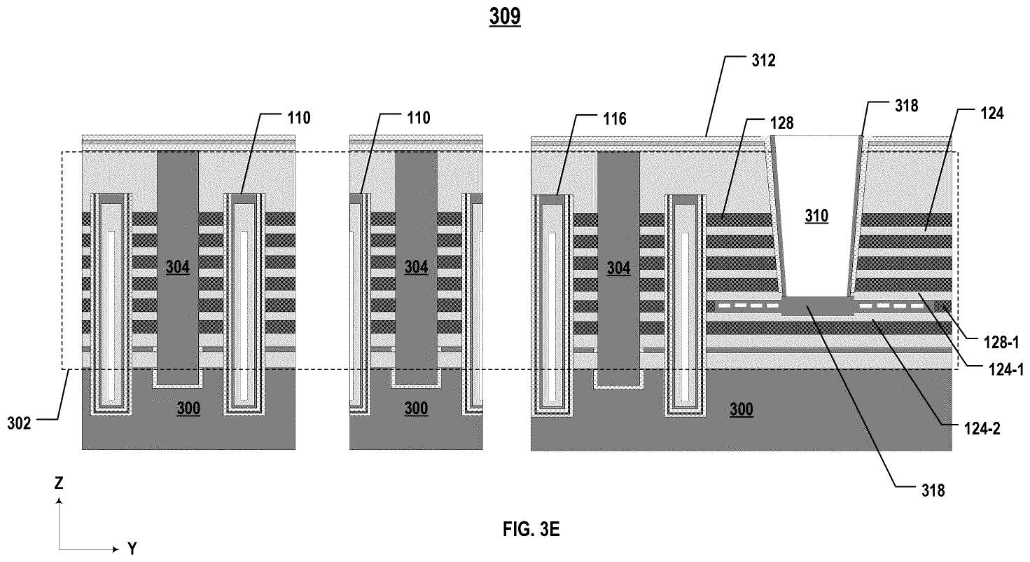

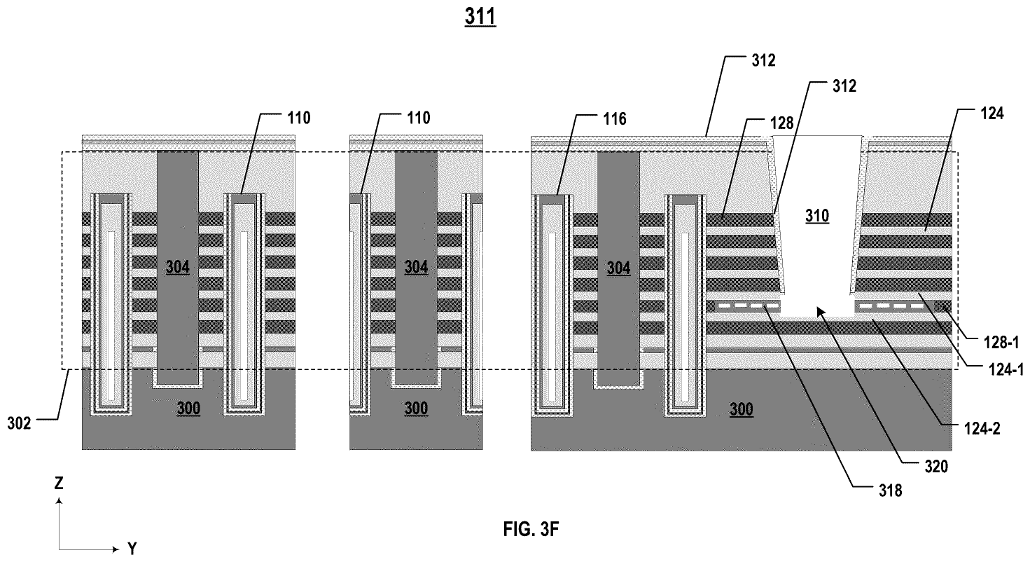

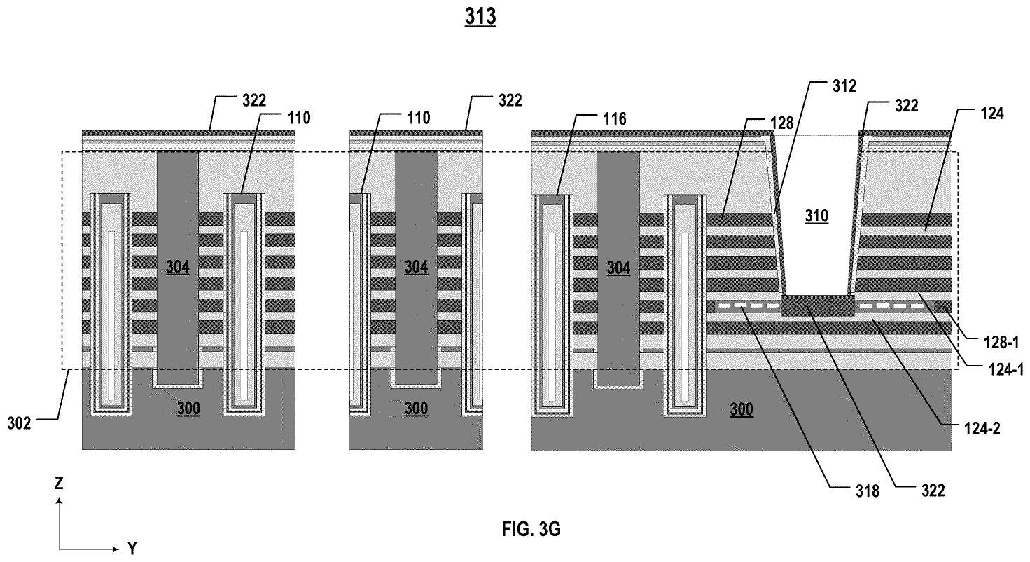

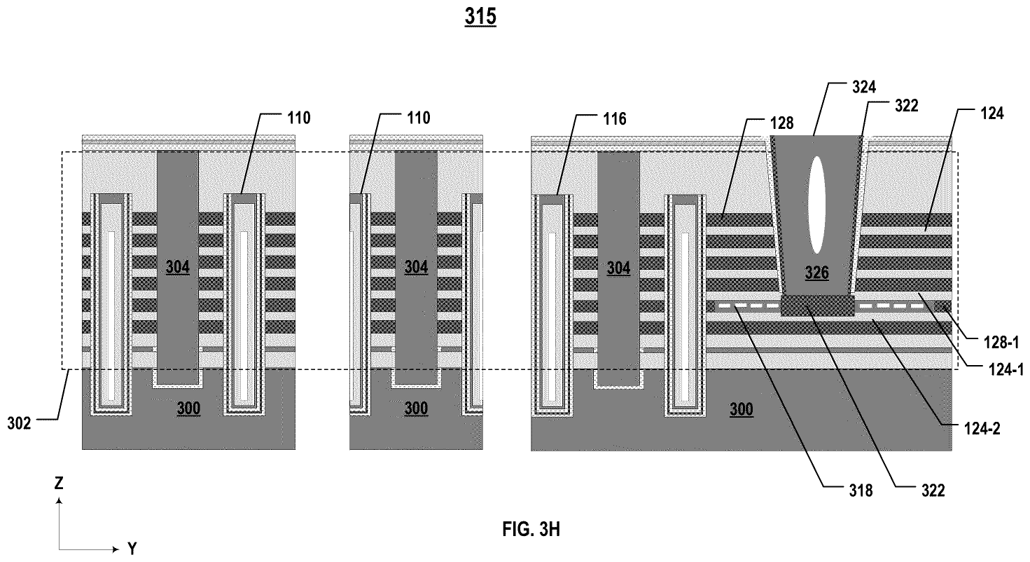

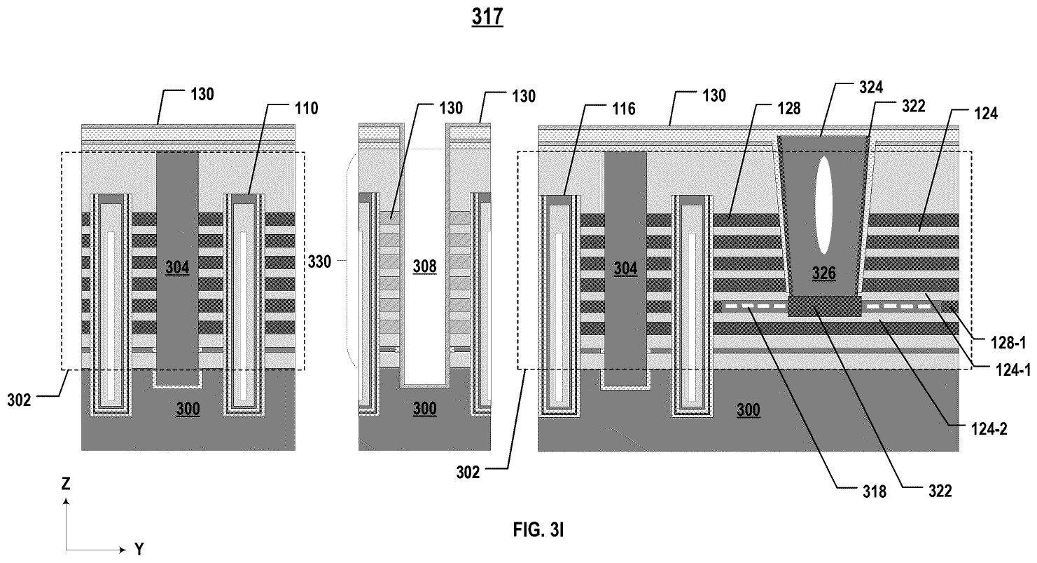

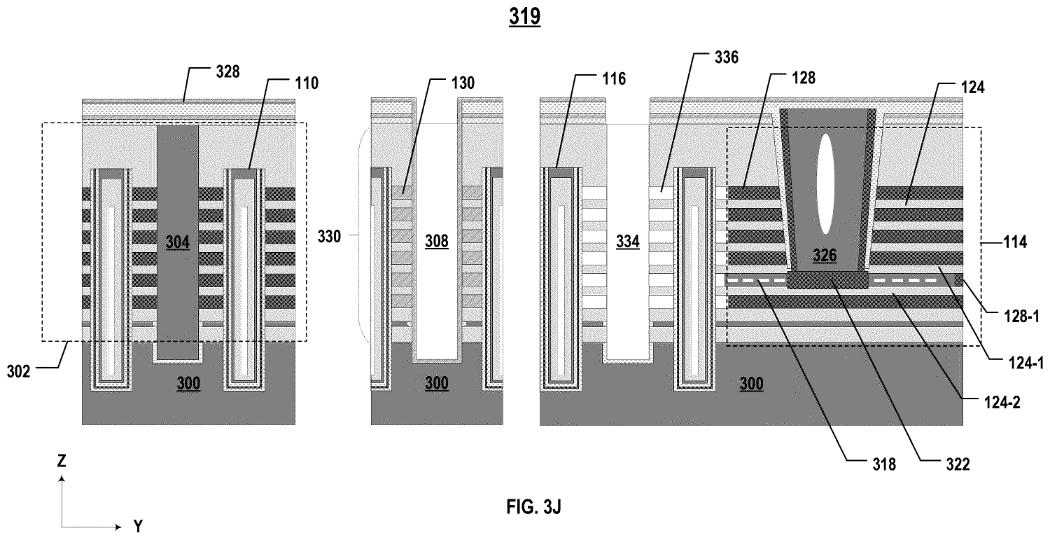

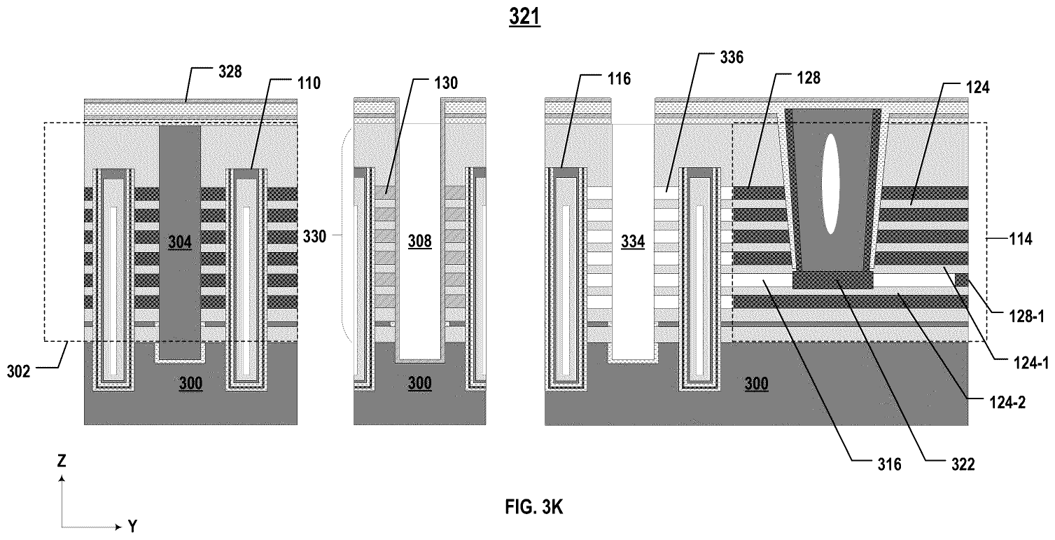

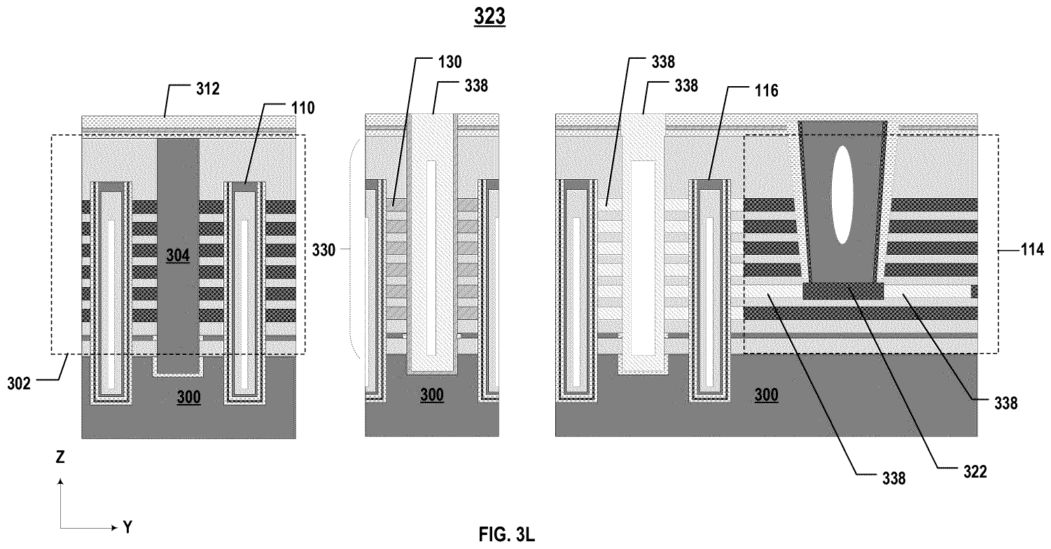

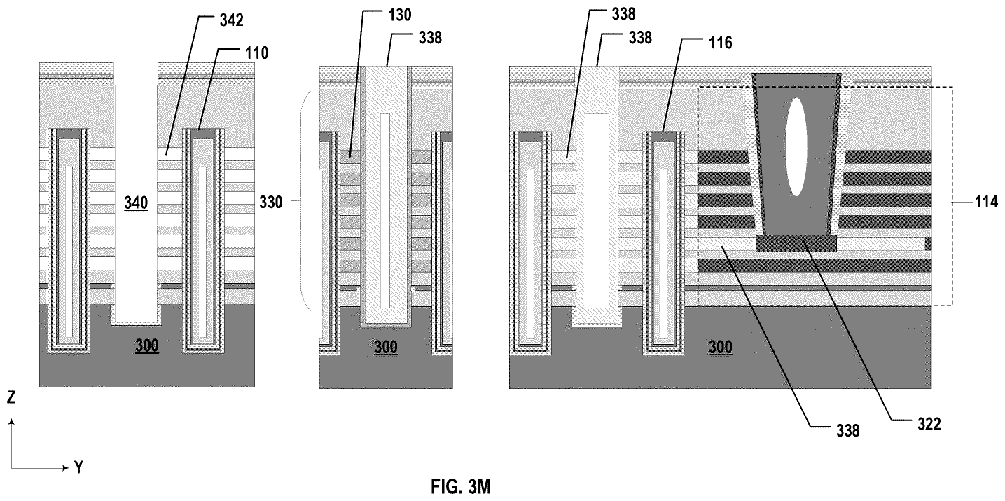

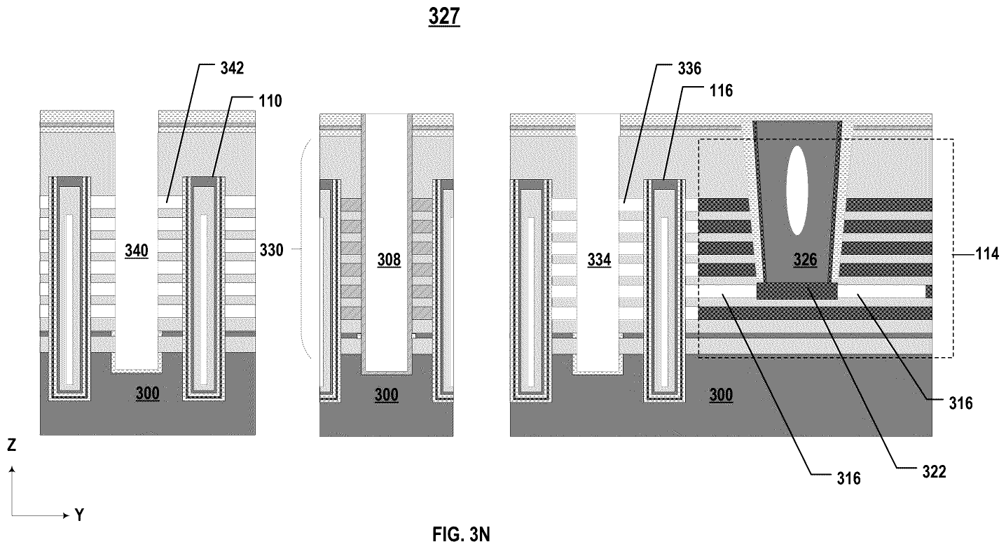

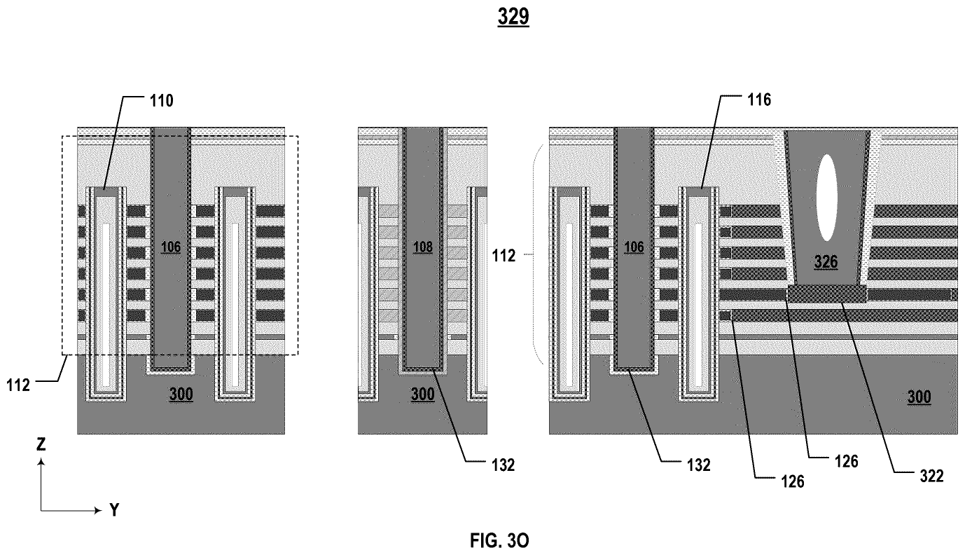

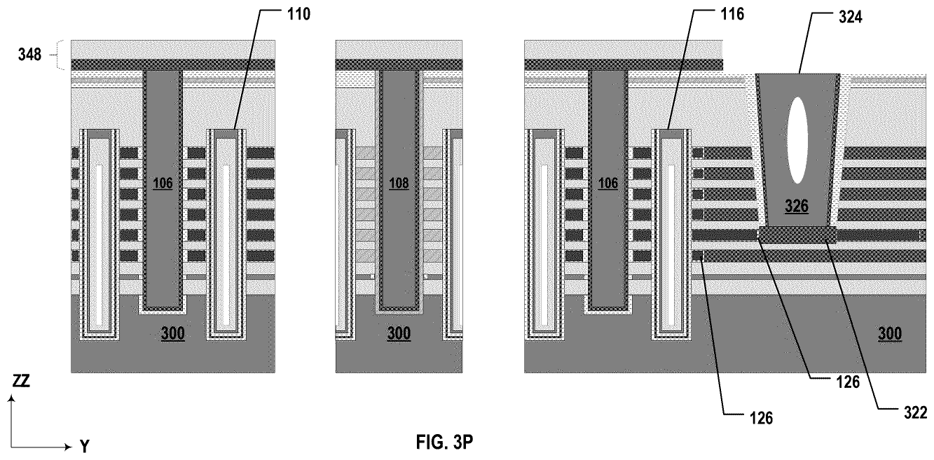

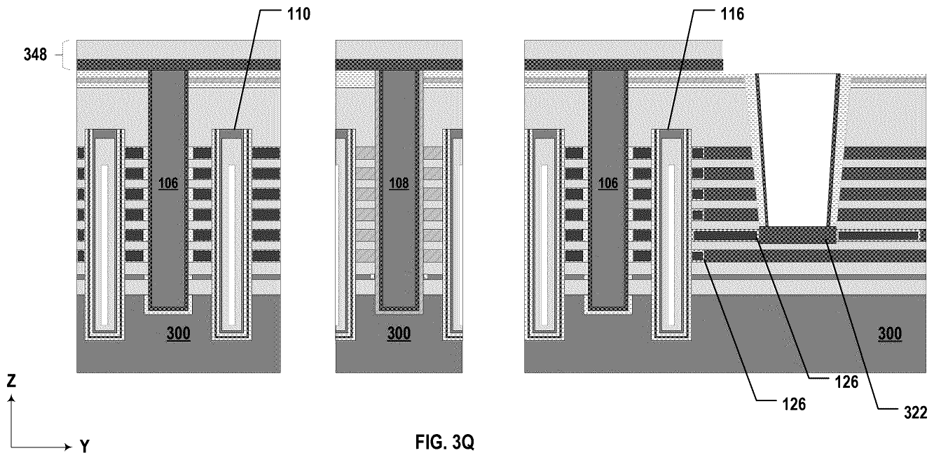

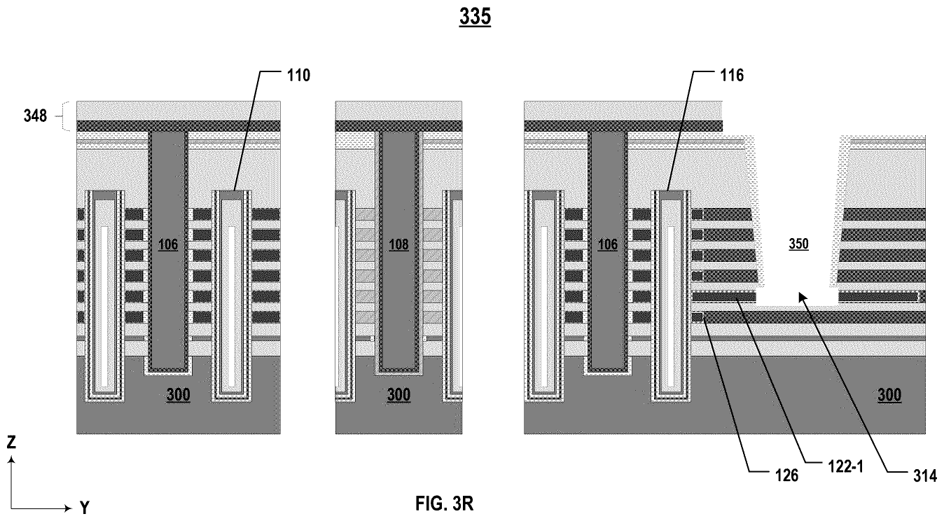

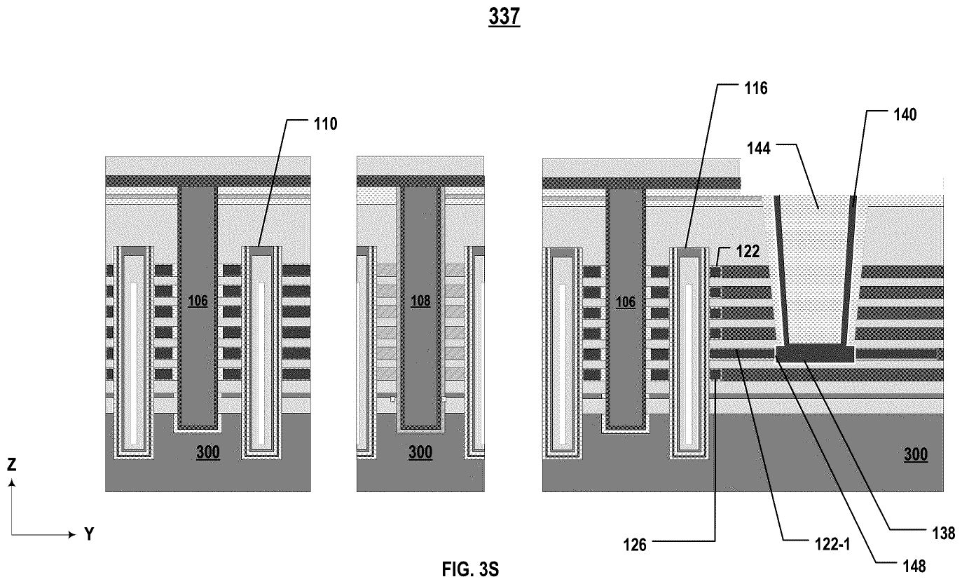

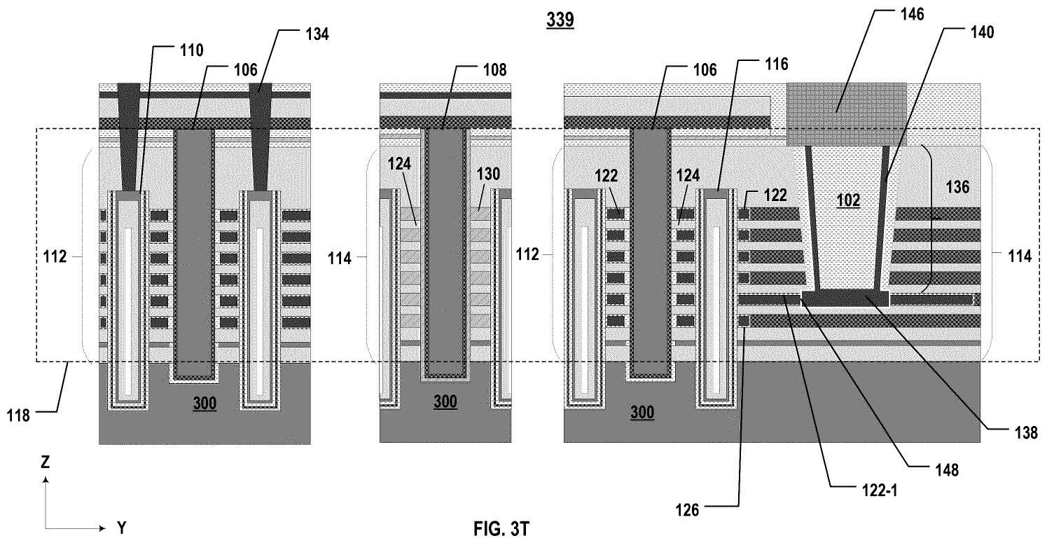

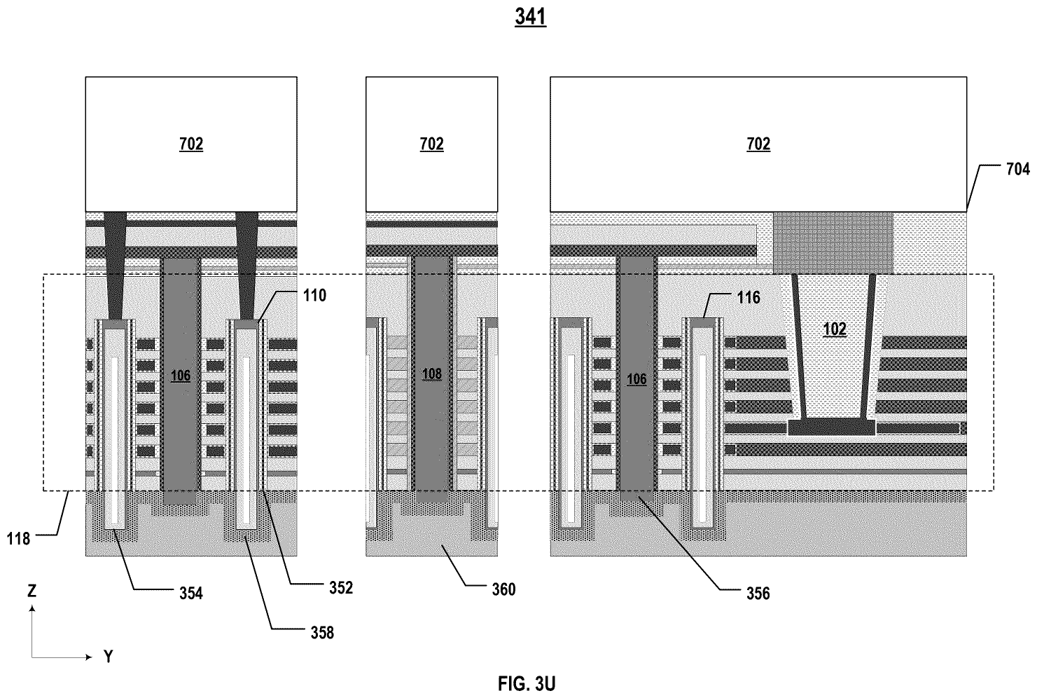

FIG. 1B shows various cross-sectional side views of 3D memory device 10 having contact structures 102, according to some aspects of the present disclosure. Among the cross-sectional side views, one view may be along the A-A′ direction in core array region 101 in FIG. 1A, another cross-section may be along the B-B′ direction in the intermediate region between core array region 101 and connection region 103, and the other may be along the C-C′ direction in connection region 103 in FIG. 1A. In some implementations, 3D memory device 10 can also be an exemplary implementation of 3D memory device 11 in FIG. 1C or 3D memory device 12 in FIG. 1D, except that the intermediate region, between core array region 101 and connection region 103, may have different arrangements, with/without isolation structures 108. It can be understood that certain implementations proposed in the present disclosure can be applicable to 3D memory device 11 in FIGS. 1C and 3D memory device 12 n FIG. 1D.

As shown in FIG. 1B, in some implementations, a stack structure 118 can be formed on a substrate 120. Substrate 120 can include silicon (e.g., single crystalline silicon), silicon germanium (SiGe), gallium arsenide (GaAs), germanium (Ge), silicon on insulator (SOI), or any other suitable materials, according to some implementations. In some examples, substrate 120 can include single crystalline silicon, which is part of the wafer on which 3D memory device 10 is fabricated, either in its native thickness or being thinned. In some implementations, substrate 120 may include, for example, polysilicon, which is a semiconductor layer replacing the part of the wafer on which 3D memory device 10 is fabricated.

It is noted that y and z axes are included in FIG. 1B to further illustrate the spatial relationship of the components in 3D memory device 10. Substrate 120 of 3D memory device 10 may include two lateral surfaces extending laterally in the x-y plane: a top surface on the front side of the wafer on which stack structure 118 can be formed, and a bottom surface on the backside opposite to the front side of the wafer. The z-axis is perpendicular to both the x and y axes. As used herein, whether one component (e.g., a layer or a device) is “on,” “above,” or “below” another component (e.g., a layer or a device) of 3D memory device 10 may be determined relative to substrate 120 of 3D memory device 10 in the z-direction (the vertical direction perpendicular to the x-y plane) when substrate 120 is positioned in the lowest plane of 3D memory device 10 in the z-direction. The same notion for describing the spatial relationship is applied throughout the present disclosure.

It can also be understood that in some implementations, substrate 120 may be removed during the fabrication processes to bring the connections between the memory cells (such as a common source line of the memory cells). It is apparent that FIG. 1B still illustrates substrate 120 for an orientation purpose and does not depict configurations of the final product of 3D memory device 10.

Stack structure 118 may include conductive stack structure 112 and dielectric stack structure 114, as shown in FIGS. 1A and 1B. In some implementations, stack structure 118 may further include one or more layers over/on conductive stack structure 112 and/or dielectric stack structure 114, such as one or more dielectric layers and/or one or more interconnection layers. In some implementations, conductive stack structure 112 may be arranged in part of core array region 101, corresponding to channel structures 110. Furthermore, at the periphery of contact structures 102, conductive stack structure 112 may be arranged in part of connection region 103, corresponding to dummy channel structures 116, as shown in FIG. 1B. Dielectric stack structure 114 may be arranged in another part of connection region 103, corresponding to contact structures 102.

In some implementations, when isolation structure 108 is disposed between two aligned slit structures 106 in the x-direction, as shown in FIG. 1A, dielectric stack structure 114 may also be arranged in the intermediate region, corresponding to isolation structure 108. Each isolation structure 108 can extend, in the z-direction, through dielectric stack structure 114 in the intermediate region. In some examples, dielectric stack structure 114 in the intermediate region, corresponding to isolation structure 108, may include different dielectric layers from dielectric stack structure 114 in connection region 103, corresponding to contact structures 102. For instance, dielectric stack structure 114 in the intermediate region, corresponding to isolation structures 108, may include interleaved first dielectric layers and third dielectric layers, which are different from the interleaved of first dielectric layers and second dielectric layers in connection region 103. Details will be provided below. In the present disclosure, the terms “interleaved” and “alternating” are used to describe that two elements may be arranged in a sequence in such a way that they are interspersed or mixed with each other.

As shown in FIG. 1B, conductive stack structure 112 may include interleaved conductive layers 122 and first dielectric layers 124. Conductive layers 122 and first dielectric layers 124 can alternate in the vertical direction (the z-direction or the thickness direction). One conductive layer 122 and one first dielectric layer can be recognized as a layer pair in a plurality of layer pairs of conductive stack structure 112. The number of layer pairs in conductive stack structure 112 may determine the number of memory cells in 3D memory device 10. In some examples, the outer surfaces of conductive layer 122 in conductive stack structure 112 may be covered or coated with high dielectric constant (high-k) gate dielectric layers 126. As described below in detail with respect to the fabrication processes, high-k gate dielectric layers 126 may be formed before the formation of one or more conductive materials of conductive layers 122, such that the one or more conductive materials may be surrounded/covered by high-k gate dielectric layers 126 in conductive layers 122.

Conductive layers 122 in conductive stack structure 112 can include conductive materials including, but not limited to, tungsten (W), cobalt (Co), copper (Cu), aluminum (Al), titanium nitride (TiN), polycrystalline silicon (polysilicon), doped silicon, silicides, or any combination thereof. First dielectric layers 124 in conductive stack structure 112 can include dielectric materials including, but not limited to, silicon oxide, silicon nitride, silicon oxynitride, or any combination thereof. High-k gate dielectric layers 126 can include high-k dielectric materials, such as aluminum oxide (AlO), hafnium oxide (HfO), zirconium oxide (ZrO), or any combinations thereof. In some examples, conductive layers 122 may include at least one of W or TiN, while first dielectric layers 124 may include silicon oxide.

In some implementations, 3D memory device 10 can be a NAND Flash memory device which includes NAND memory strings (in the form of channel structures 110 in core array region 101), and NAND memory strings can be formed extending through conductive stack structure 112 in the z-direction. A portion of each conductive layer 122 in conductive stack structure 112 can function as a gate line of the NAND memory strings, while another portion of each conductive layer 122 can serve as a word line that connects with a respective gate line, extend laterally in the x-direction (a.k.a., the word line direction) across core array region 101, and connect with a corresponding contact structure 102 in connection region 103.

On the other hand, dielectric stack structure 114 in connection region 103 may include interleaved first dielectric layers 124 and second dielectric layers 128. First dielectric layers 124 of dielectric stack structure 114 herein can be an extension/continuation of and identical to first dielectric layers 124 of conductive stack structure 112. In the fabrication processes, first dielectric layers 124 may be formed extending across core array region 101 and connection region 103. First dielectric layers 124 and second dielectric layers 128 can alternate in the vertical direction (i.e., the z-direction). In some examples, first dielectric layers 124 and second dielectric layers 128 can have different dielectric materials. In some examples, first dielectric layers 124 may include silicon oxide, and second dielectric layers 128 may include silicon nitride.

As shown in FIG. 1B, 3D memory device 10 can include channel structures 110 in core array region 101. Each channel structure 110 can extend vertically in the z-direction through interleaved conductive layers 122 and first dielectric layers 124 of conductive stack structure 112 into substrate 120. In the present disclosure, conductive stack structure 112 that corresponds to channel structures 110 may refer to that region in core array region 101 through which channel structures 110 penetrate. In some implementations, 3D memory device 10 can also include dummy channel structures 116 in connection region 103. Each dummy channel structure 116 can extend vertically through conductive stack structure 112 in connection region 103 into substrate 120, as shown in FIG. 1B. 3D memory device 10 can further include slit structures 106 across both core array region 101 and connection region 103. Each slit structure 106 can extend vertically through interleaved conductive layers 122 and first dielectric layers 124 of conductive stack structure 112 into substrate 120 and can extend laterally across core array region 101 and connection region 103, as shown in FIG. 1B.

In some implementations, as shown in the B-B′ cross-sectional side view in FIG. 1B, isolation structure 108 can be arranged between two discontinuous slit structures 106 aligned in the x-direction. Isolation structure 108 may extend, in the z-direction, through dielectric stack structure 114 in the intermediate region, as shown in FIG. 1B. Dielectric stack structure 114, through which isolation structure 108 extends, may be different from dielectric stack structure 114 through which contact structure 102 extends. More specifically, dielectric stack structure 114 may include a first dielectric stack structure and a second dielectric stack structure. The first dielectric stack structure may be different from the second dielectric stack structure. The first dielectric stack structure may correspond to contact structure 102, while the second dielectric stack structure may correspond to isolation structure 108. The first dielectric stack structure may include interleaved first dielectric layers 124 and second dielectric layers 128. The second dielectric structure may include interleaved first dielectric layers 124 and third dielectric layers 130, as shown in FIG. 1B. Second dielectric layers 128 may be different from third dielectric layers 130. In some examples, second dielectric layers 128 may include silicon nitride layers, while third dielectric layers 130 may include silicon oxide layers.

As shown in FIG. 1B, slit structure 106 can include a slit spacer 132 that separates conductive layers 122 in conductive stack structure 112 between different blocks 104. In some implementations, slit structure 106 may be an insulating structure. In other words, slit structure 106 may not include any contact (e.g., a source contact) and thus, does not introduce parasitic capacitance and leakage current with conductive layers 122. In some implementations, slit structure 106 may include a front-side source contact which may further include one or more conductive materials (e.g., W, polysilicon, and/or TiN) circumscribed by slit spacer 132. As described below in detail, during a gate replacement process, a slit opening can serve as a passageway for filling conductive layers 122, and subsequently, the slit opening can be transformed into slit structure 106.

As shown in FIG. 1B, in some implementations, 3D memory device 10 may further include a plurality of drain select gate (DSG) channel structures 134 above and in contact with the upper ends of channel structures 110, respectively. In some implementations, in core array region 101, 3D memory device 10 may further include one or more semiconductor layers (e.g., a polysilicon layer surrounded by a spacer), one or more stop layers (e.g., a silicon nitride layer), and one or more dielectric layers (e.g., silicon oxide layers) as part of stack structure 118 or stacked over stack structure 118. In other words, the number of layers in stack structure 118, as illustrated in FIG. 1B, serves purely as a reference and merely for the sake of simplifying the descriptions. It is apparent that this depiction (including the respective vertical ranges of stack structure 118/conductive stack structure 112/dielectric stack structure 114) is not intended to constrain or limit the scope of the present disclosure.

In core array region 101, each DSG channel structure 134 may extend through the one or more semiconductor layers (e.g., a polysilicon layer surrounded by a spacer), the one or more stop layers (e.g., a silicon nitride layer), and/or the one or more dielectric layers (e.g., silicon oxide layers) and connect with the upper end of a corresponding channel structure 110. In some examples, 3D memory device 10 in core array region 101 may include one or more interlayer dielectric (ILD) layers incorporating various local contacts (such as bit line contacts) above and in contact with DSG channel structures 134. The local contacts may include conductive materials including, but not limited to, W, Co, Cu, Al, silicides, or any combination thereof. The ILD layers can include dielectric materials including, but not limited to, silicon oxide, silicon nitride, silicon oxynitride, low-k dielectrics, or any combination thereof. In some implementations, dummy channel structures 116 in connection region 103 may not have the DSG channel structures.

In some implementations, 3D memory device 10 can include stack structure 118 having layers with uniform thicknesses (in the z-direction). For instance, the thickness of each first dielectric layer 124 can be the same in core array region 101 and connection region 103. With a gate replacement process, conductive layers 122 of conductive stack structure 112, coated with high-k gate dielectric layers 126, can replace part of second dielectric layers 128 of a stack structure initially formed, while another part of second dielectric layers 128, in connection region 103, may remain intact. Accordingly, contact structures 102 may extend through the remaining second dielectric layers 128 (including interleaved first dielectric layers 124 and second dielectric layers 128) in connection region 103 and serve as a substitution of staircase structures, as shown in FIG. 1B.

As shown in FIG. 1B, in some implementations, each contact structure 102 may include a contact member 136 extending, in the z-direction, through dielectric stack structure 114 in connection region 103, and an interconnect member 138 extending laterally, e.g., in the y-direction. Interconnect member 138 may extend laterally (e.g., in the y-direction) to connect with one conductive layer 122-1 (a.k.a., a first conductive layer 122-1) extended from conductive stack structure 112 (serving as a word line) to achieve a word line pick-up/fan-out. More specifically, conductive stack structure 112 may include first conductive layer 122-1, and first conductive layer 122-1 may extend laterally (e.g., in the y-direction) from conductive stack structure 112 across connection region 103 to a region adjacent to contact structures 102, such that interconnect member 138 can connect with first conductive layer 122-1. To some extent, first conductive layer 122-1 can be viewed as a portion of conductive stack structure 112 and/or an extension of conductive stack structure 112 to connection region 103.

In some examples, contact member 136 may include a contact material 140, a contact spacer 142 circumscribing contact material 140, and a contact filler 144 circumscribed by contact material 140. Interconnect member 138 may be arranged at the bottom/end of contact member 136 to electrically couple with contact material 140 of contact member 136. Contact material 140 of contact member 136 and interconnect member 138 can include conductive materials including, but not limited to, W, Co, Cu, Al, TiN, polysilicon, doped silicon, silicides, or any combination thereof. Contact spacer 142 can include dielectric materials including, but not limited to, silicon oxide, silicon nitride, silicon oxynitride, or any combination thereof. In some examples, each contact material 140 and interconnect member 138 may include TiN, W, or a combination of TiN and W, and contact spacer 142 may include silicon oxide. In some examples, contact material 140 may be selected to be identical to conductive material(s) of first conductive layer 122-1. In other examples, contact material 140 may be different from the conductive material(s) of first conductive layer 122-1.

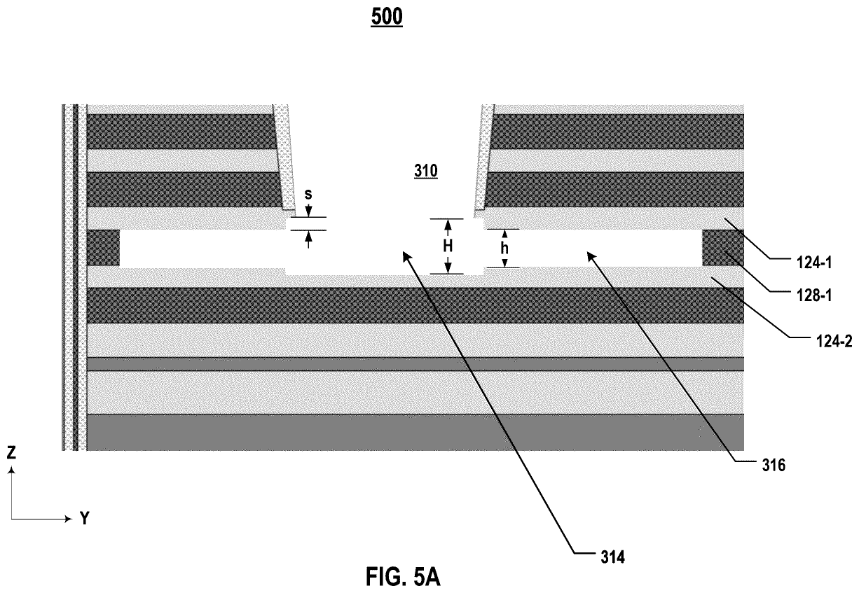

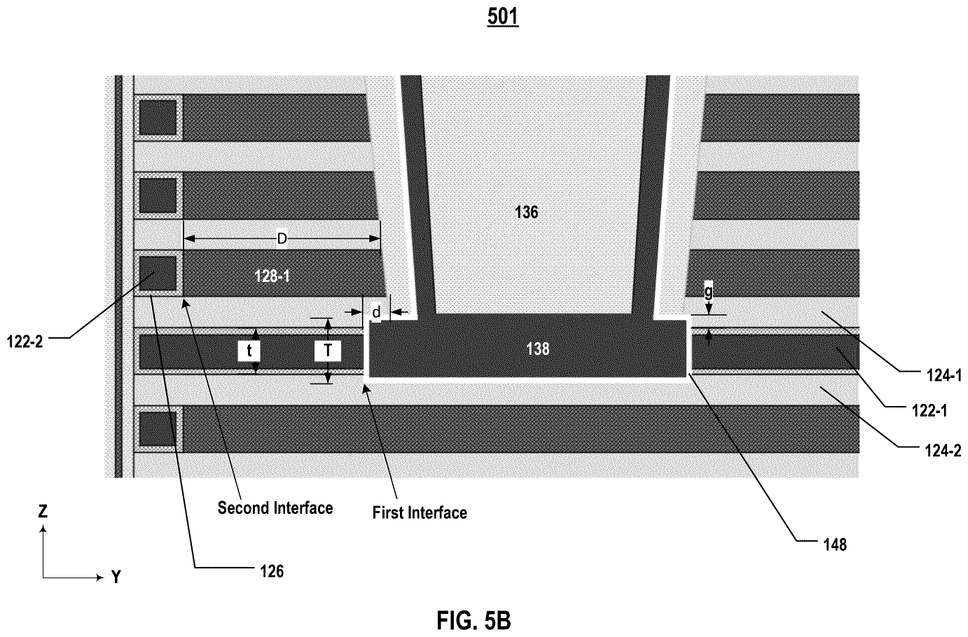

In some implementations, the thickness (in the z-direction) of interconnect member 138 may be greater than the thickness of first conductive layer 122-1 connected with interconnect member 138. In a gate replacement process, conductive layers 122, including first conductive layer 122-1 connected with interconnect member 138 later, may replace part of second dielectric layers 128. In the gate replacement process, conductive layers 122 can be formed with one or more conductive materials coated with high-k gate dielectric layers 126, according to some implementations. Before forming interconnect member 138, a lateral recess, extending in the y-direction, can be formed, and the thickness of the lateral recess may be configured to be greater than the thickness of first conductive layer 122-1. During forming the lateral recess, the vertical high-k gate dielectric layer covering first conductive layer 122-1 (connected with interconnect member 138) can also be removed. Subsequently, a glue layer 148 may be formed over the sidewall of the lateral recess. Details of the sizes and configurations of components in contact structure 102 will be described below, with reference to FIGS. 5A and 5B.

In the same gate replacement process, conductive layers 122, other than first conductive layer 122-1, can be formed to connect with the remaining second dielectric layers 128 in connection region 103. As a consequence, high-k gate dielectric layers 126 can be arranged and sandwiched between second dielectric layers 128 and conductive layers 122 and not connected with interconnect member 138 of contact structure 102. Through the fabrication processes, glue layer 148 can be arranged and sandwiched between first conductive layer 122-1 and the one or more conductive materials of interconnect member 138, as shown in FIG. 1B.

In some implementations, part of stack structure 118 over contact member 136 may be selectively removed to expose contact material 140 below. Subsequently, a contact pad 146 may be formed over contact member 136 to establish the electrical connection with contact material 140, as shown in FIG. 1B. In some implementations, contact pad 146 may include one or more conductive materials, e.g., TiN, W, or a combination of TiN and W.

In some implementations, 3D memory device 10 may include multiple contact structures 102 each extending, in the z-direction, through dielectric stack structure 114 in connection region 103 at different depths to be electrically connected with conductive layers 122 at different levels, respectively. More specifically, each contact structure 102 may be configured to connect with a corresponding conductive layer 122 at a specific depth. Through this manner, conductive layers 122 can serve as word lines, and contact structures can replace the conventional staircase structures to achieve word line pick-up/fan-out.

It can be understood that, as shown in the cross-sectional side view of FIG. 1B, conductive layer 122-1 can be the first conductive layer that is connected with interconnect member 138 of contact structure 102 at the specific depth. First conductive layer 122-1 will no longer be a (first) conductive layer corresponding to another contact structure 102 having interconnect member 138 at a different depth. Namely, first conductive layer 122-1 specifically corresponds to a specific contact structure 102 as first conductive layer 122-1 is connected with interconnect member 138 of contact structure 102.

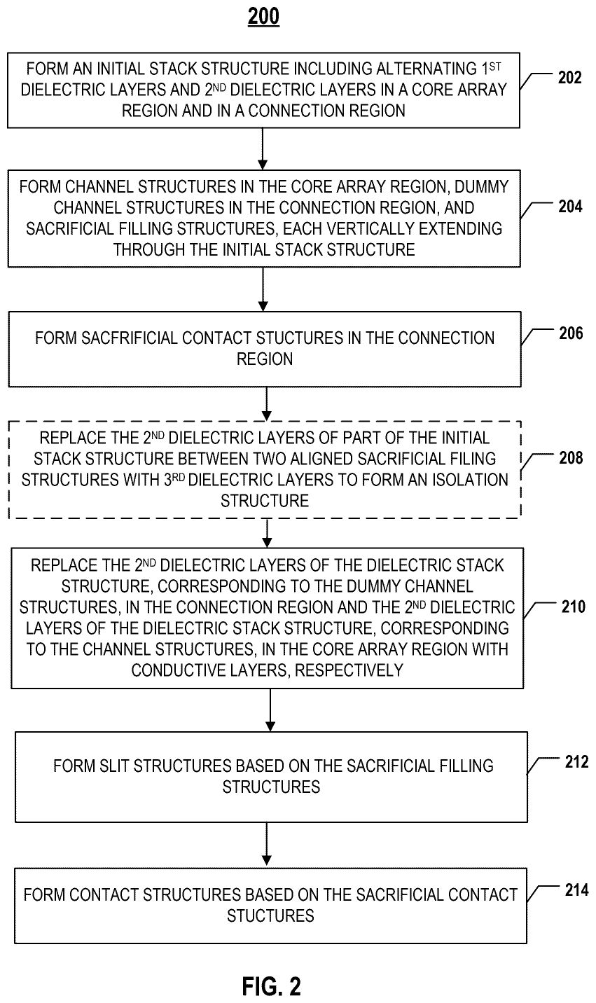

FIG. 2 illustrates a flowchart of a method 200 for forming a 3D memory device having contact structures, according to some aspects of the present disclosure. FIGS. 3A-3U illustrate fabrication processes for forming a 3D memory device having contact structures 102, according to some aspects of the present disclosure. Each figure of FIGS. 3A-3U includes various cross-sectional side views of the 3D memory device, according to some aspects of the present disclosure. Among the cross-sectional side views of each figure, one cross-sectional view may be taken along the A-A′ direction in core array region 101, another cross-section view may be taken along the B-B′ direction in the intermediate region between core array region 101 and connection region 103, and the other cross-section view may be taken along the C-C′ direction in connection region 103, in FIG. 1A. Although the present disclosure solely uses FIG. 1A as an exemplary implementation to describe the fabrication processes regarding FIGS. 3A-3U, it can be understood that 3D memory device 11 in FIG. 1C or 3D memory device 12 in FIG. 1D can apply part of the fabrication processes for similar applications.

Next, FIG. 2 will be described together with FIGS. 3A-3U. It is understood that the operations shown in method 200 may not be exhaustive and that other operations can be performed as well before, after, or between any of the illustrated operations shown in FIG. 2. Furthermore, some of the operations may be performed simultaneously, or in a different order than that shown in FIG. 2. Examples of the 3D memory device having contact structures depicted in FIGS. 3A-3U may include 3D memory device 100 in FIG. 1A or 3D memory device 10 in FIG. 1B.

Referring to FIG. 2, method 200 may start at operation 202, in which a stack structure 302 including multiple pairs of a first dielectric layer 124 and a second dielectric layer 128 (a.k.a., a stack sacrificial layer) may be initially formed above a substrate 300. Initial stack structure 302 may include vertically interleaved first dielectric layers 124 and second dielectric layers 128, as shown in FIG. 3A. In some implementations, over the interleaved first dielectric layers 124 and second dielectric layers 128, initial stack structure 302 may include one or more dielectric layers and/or one or more semiconductor layers, depending on various applications.

First dielectric layers 124 can include dielectric materials including, but not limited to, silicon oxide, silicon nitride, silicon oxynitride, or any combination thereof. Second dielectric layers 128 can include dielectric materials including, but not limited to, silicon oxide, silicon nitride, silicon oxynitride, or any combination thereof. According to some implementations, each first dielectric layer 124 can include silicon oxide, and each second dielectric layer 128 can include silicon nitride. Initial stack structure 302 can be formed by one or more thin film deposition processes including, but not limited to, chemical vapor deposition (CVD), physical vapor deposition (PVD), atomic layer deposition (ALD), or any combination thereof.

In some implementations, substrate 300 can include silicon (e.g., single crystalline silicon), silicon germanium (SiGe), gallium arsenide (GaAs), germanium (Ge), silicon on insulator (SOI), or any other suitable materials. In some implementations, substrate 300 may include single crystalline silicon, which is part of the wafer on which a semiconductor structure 301 is fabricated, either in its native thickness or being thinned. In some implementations, substrate 300 may include, for example, polysilicon, which is a semiconductor layer replacing the part of the wafer on which semiconductor structure 301 is fabricated.

Subsequently, method 200 may proceed to operation 204, in which channel structures 110 that extend, in the z-direction, through initial stack structure 302 may be formed in core array region 101, as shown in FIG. 3A. In some implementations, to form each channel structure 110, a channel hole extending vertically through initial stack structure 302 in core array region 101 can be formed. Subsequently, a memory layer (including a blocking layer, a storage layer, and a tunneling layer) and a channel layer may be sequentially formed over the sidewalls and bottom surfaces of the channel hole. In some implementations, to form each channel structure 110, a channel hole extending vertically through initial stack structure 302 can be formed, and a high-k gate dielectric layer, a memory layer, and a channel layer may be sequentially formed over the sidewalls of the channel hole. In some implementations, the fabrication processes for forming the channel hole of each channel structure 110 may include wet etching and/or dry etching, such as deep-ion reactive etching (DRIE).

In some implementations, the memory layer may be first deposited along the sidewalls and bottom surface of the channel hole, and the semiconductor channel may then be deposited over the memory layer. The blocking layer, storage layer, and tunneling layer can be subsequently deposited in this order using one or more thin film deposition processes, such as ALD, CVD, PVD, any other suitable processes, or any combination thereof, to form the memory layer. The channel layer can then be formed by depositing a semiconductor material, such as polysilicon, over the tunneling layer of the memory layer using one or more thin film deposition processes, such as ALD, CVD, PVD, any other suitable processes, or any combination thereof. In some implementations, a first silicon oxide layer, a silicon nitride layer, a second silicon oxide layer, and a polysilicon layer (a “SONO” structure) can be subsequently deposited to form the memory layer (including the blocking layer, storage layer, and tunneling layer) and the channel layer of each channel structure 110.

In some implementations, a high-k gate dielectric layer may be formed before the formation of the memory layer. That is, the high-k gate dielectric layer, memory layer (including the blocking layer, storage layer, and tunneling layer), and the channel layer can be sequentially formed in this order along the sidewalls and bottom surface of the channel hole. In some implementations, the high-k gate dielectric layer may be first deposited along the sidewalls and bottom surfaces of the channel hole, the memory layer may then be deposited over the high-k gate dielectric layer, and the semiconductor channel may then be deposited over the memory layer. The high-k gate dielectric layer can be formed by depositing high-k dielectric materials, such as aluminum oxide, using one or more thin film deposition processes, such as ALD, CVD, PVD, any other suitable processes, or any combination thereof.

The blocking layer, storage layer, and tunneling layer can be subsequently deposited in this order using one or more thin film deposition processes, such as ALD, CVD, PVD, any other suitable processes, or any combination thereof, over the high-k gate dielectric layer to form the memory layer. The channel layer can then be formed by depositing a semiconductor material, such as polysilicon, over the tunneling layer of the memory layer using one or more thin film deposition processes, such as ALD, CVD, PVD, any other suitable processes, or any combination thereof. In some implementations, an aluminum oxide layer, a first silicon oxide layer, a silicon nitride layer, a second silicon oxide layer, and a polysilicon layer (a.k.a., a “SONO” structure) may be subsequently deposited to form the high-k gate dielectric layer, the memory layer, and the channel layer of channel structures 110, according to some implementations of the present disclosure.

In some implementations, dummy channel structures 116 that extend, in the z-direction, through initial stack structure 302 may be formed in connection region 103, in the same process of forming channel structures 110. That is, channel structures 110 and dummy channel structures 116 can be simultaneously formed to extend through first dielectric layers 124 and second dielectric layers 128 in core array region 101 and connection region 103, respectively. At this stage, in some examples, dummy channel structures 116 in connection region 103 may have the same structures/configurations as channel structures 110 in core array region 101.

In some implementations, as illustrated in FIG. 3A, dummy channel structures 116 can be formed in connection region 103 of semiconductor structure 301, in the same process of forming channel structures 110 in core array region 101 thereof. To form each dummy channel structure 116, a dummy channel hole, which is another opening extending vertically through initial stack structure 302, can be formed in connection region 103 simultaneously as forming the channel hole for each channel structure 110 by the same wet etching and/or dry etching, such as DRIE. Subsequently, dummy channel structures 116 can then be formed simultaneously as channel structures 110 by the same thin film deposition processes, such as ALD, CVD, PVD, any other suitable processes, or any combination thereof, which deposit a memory layer (including a blocking layer, a storage layer, and a tunneling layer) and a channel layer, or another implementation that includes a high-k gate dielectric layer, a memory layer (including a blocking layer, a storage layer, and a tunneling layer), and a channel layer. It can be understood that in some examples, dummy channel structures 116 may be formed in separate processes from forming channel structures 110.

At operation 204, sacrificial filling structure 304 may be formed to extend, in the z-direction, through first dielectric layers 124 and second dielectric layers 128 of initial stack structure 302 and extend laterally across core array region 101 and connection region 103. Subsequently, sacrificial filling structure 304 can be transformed into slit structures 106 in FIGS. 1A and 1B (in some examples, may be converted into isolation structure 108 as well). To form each sacrificial filling structure 304, a slit opening may be formed to extend vertically through initial stack structure 302 as well as, e.g., one or more other dielectric layers stacked over initial stack structure 302, into substrate 300. In some implementations, the depth of each slit opening may be greater than the depth of each channel hole. Slit opening can extend laterally, in the x-direction, across core array region 101 and connection region 103. In some implementations, the fabrication processes for forming each slit opening may include wet etching and/or dry etching, such as DRIE. The etching processes that penetrate through initial stack structure 302 may not stop at the top surface of substrate 300 and may continue to etch part of substrate 300 to ensure that each slit opening extends vertically all the way through all first dielectric layers 124 and second dielectric layers 128 of initial stack structure 302.

Subsequently, each slit opening can be filled with a sacrificial layer using one or more thin film deposition processes, such as CVD, PVD, ALD, or any combination thereof. In some implementations, the sacrificial layer may be different from the material(s) of first dielectric layers 124 and second dielectric layers 128 and may include polysilicon or carbon. In some examples, each sacrificial filling structure 304 may include polysilicon.

In some implementations, to create the slit openings for forming slit structures 106, a plurality of slit holes may be formed each extending, in the z-direction, through initial stack structure 302. In some examples, the slit holes may be aligned in the x-direction. Multiple slit holes of the slit holes may be enlarged to connect with one another, and accordingly, one slit opening can be formed. In some implementations, to form isolation structure 108 as illustrated in FIG. 1A, multiple slit holes of the slit holes at each side of one or more specific slit holes can be connected, by removing part of initial stack structure 302 between each pair of two adjacent slit holes, to form one slit opening. In some examples, the one or more specific slit holes for forming isolation structure 108 may be located in an area between core array region 101 and connection region 103. It can be understood that the above processes are provided as an example for demonstrating the formation of slit openings, and other processes may also be applied. The present disclosure does not limit thereto.

In some implementations, one or more cap layers may be formed over the top surface of semiconductor structure 301 (e.g., over initial stack structure 302). The one or more cap layers can be deposited over semiconductor structure 301 using one or more thin film deposition processes, such as CVD, PVD, ALD, or any combination thereof. In the subsequence processes, the one or more cap layers can serve as, e.g., a protection/mask layer in the subsequent fabrication processes.

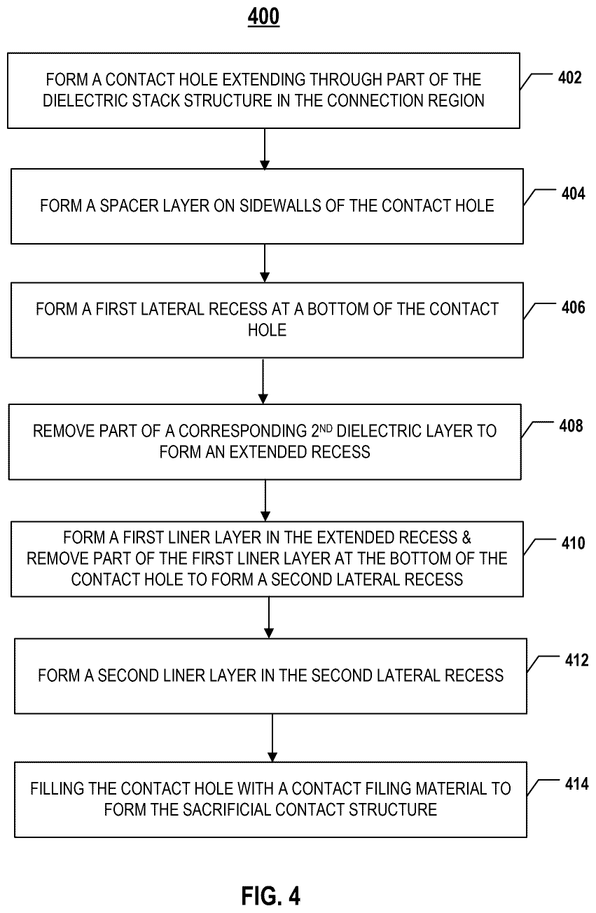

Method 200 may proceed to operation 206, in which sacrificial contact structures may be formed in connection region 103. The sacrificial contact structures can be transformed into contact structures 102 as illustrated in FIGS. 1A and 1B. That is, contact structure 102 in FIGS. 1A and 1B can be formed based on a sacrificial contact structure. FIG. 4 illustrates a flowchart of a method 400 for forming sacrificial contact structures, according to some aspects of the present disclosure. Details about forming a sacrificial contact structure will be described according to FIG. 4, together with reference to the fabrication processes shown in FIGS. 3B-3C.

Method 400 in FIG. 4 may proceed to operation 402, in which contact holes 310 may be formed in connection region 103. Contact holes 310 may extend, in the z-direction (i.e., in the vertical direction), through initial stack structure 302 including first dielectric layers 124 and second dielectric layers 128. It can be understood that each contact hole 310 can be formed having a different depth to expose a different second dielectric layer 128 of initial stack structure 302 for the subsequent word line fan-out purpose.

In the fabrication processes, to form each contact hole 310, initial stack structure 302 can be patterned using lithography followed by wet etching and/or dry etching. As a consequence, part of initial stack structure 302 in connection region 103, as well as the one or more layers stacked over the part of initial stack structure 302 can be removed. For instance, a mask layer (or the existing cap layers) can be applied to expose the part of initial stack structure 302 where a corresponding contact structure 102 is to be formed but shield another part of initial stack structure 302. Subsequently, the exposed part of initial stack structure 302 can be selectively removed to expose a first dielectric layer 124-1, which is subsequently removed.

Method 400 may proceed to operation 404. At operation 404, a spacer layer 312 may be first formed over the sidewalls of each contact hole 310 and at the bottom of each contact hole 310 to cover the exposed first dielectric layer 124-1. Subsequently, the additional removal process may be performed through contact hole 310, according to some implementation. For instance, one or more etchants may be applied from contact holes 310 to remove spacer layer 312 at the bottom of each contact hole 310 as well as first dielectric layer 124-1 below spacer layer 312, thereby exposing second dielectric layer 128-1 beneath first dielectric layer 124-1, as shown in FIG. 3B.

According to some implementations, spacer layer 312 may also be deposited over initial stack structure 302, as shown in FIG. 3B. In some examples, each contact hole 310 may include a circular cross-section, as shown in FIG. 1A. However, the present disclosure is not limited to these features.

Method 400 may proceed to operation 406. At operation 406, a first lateral recess 314 may be formed from each contact hole 310, according to some implementations. First lateral recess 314 may be formed resulting from the removal of the exposed second dielectric layer 128-1 and another first dielectric layer 124-2 beneath second dielectric layer 128-1, according to some implementations. To form first lateral recess 314, one or more etchants may be applied from contact holes 310 to remove the exposed second dielectric layer 128-1 at the bottom of contact holes 310 as well as part of another first dielectric layer 124-2 below second dielectric layer 128-1. As a consequence, first lateral recess 314 may include a first void portion resulting from the removal of part of first dielectric layer 124-1, a second void portion by the removal of part of second dielectric layer 128-1, and a third void portion by the removal of part of first dielectric layer 124-2. In other words, first lateral recess 314 may correspond to first dielectric layer 124-1, second dielectric layer 128-1, and the other first dielectric layer 124-2, in the thickness direction (i.e., the z-direction). Consequently, contact hole 310 having first lateral recess 314 can be formed in semiconductor structure 305, as shown in FIG. 3C. In some implementations, the length of first lateral recess 314 may be carefully designed, such that it is sufficiently close to contact structure 102. In some examples, an isotropic etching may be performed such that first lateral recess 314 may extend in all lateral directions on a horizontal plane (i.e., x-y plane).

Method 400 may proceed to operation 408. At operation 408, part of the remaining second dielectric layer 128-1 may be further removed from first lateral recess 314 to form an extended lateral recess 316 as shown in FIG. 3D, according to some implementations. For example, one or more etchants in wet etching and/or dry etching may be applied through first lateral recess 314 to selectively remove second dielectric layer 128-1 without removing first dielectric layers 124. In some examples, an isotropic etching may be performed, such that extended lateral recess 316 extends over the horizontal plane (i.e., an x-y plane). Extended lateral recess 316 can be regarded as an extension of first lateral recess 314, having different thicknesses. In some implementations, extended lateral recess 316 can be formed, resulting in the only removal of the exposed second dielectric layer 128-1. As a consequence, first lateral recess 314 at the bottom of each contact hole 310 can include a first thickness (in the z-direction) corresponding first dielectric layer 124-1, second dielectric layer 128-1, and the other first dielectric layer 124-2, and extended lateral recess 316 can have a second thickness corresponding to only second dielectric layer 128-1, which is smaller than the first thickness.

FIG. 5A provides an enlarged cross-sectional side view 500 showing contact hole 310, first lateral recess 314, and extended lateral recess 316, according to some aspects of the present disclosure. In some implementations, first lateral recess 314 at the bottom of contact hole 310 may include the thickness H, and extended lateral recess 316 extending from first lateral recess 314 may include the thickness h. In some examples, the thickness h may correspond to the thickness of second dielectric layer 128-1 (and may correspond to the thickness of a first conductive layer formed later). In some examples, the thickness H of first lateral recess 314 may correspond to first dielectric layer 124-1, second dielectric layer 128-1, and the other first dielectric layer 124-2 and may be larger than the thickness h of extended lateral recess 316. In other words, H>h. In some examples, the difference between the thickness H and the thickness h is in the range of 2 nm to 6 nm. The ratio of the thickness h to the thickness H can be about 0.4 to about 0.85, according to some implementations. In some examples, a step s can be formed at one side (e.g., the top side) from the thickness h to the thickness H, as shown in FIG. 5A, and the thickness of step s may be in the range of 1 nm to 3 nm.

Method 400 may proceed to operation 410. At operation 410, a first liner layer 318 may be filled into first lateral recess 314 and extended lateral recess 316, and in some examples, formed over spacer layer 312 at the sidewalls of contact hole 310, as shown in FIG. 3E. First liner layer 318 may be patterned (e.g., through lithography) to be formed over the sidewalls and filled at the bottom of contact hole 310 in connection region 103, using one or more thin film deposition processes including, but not limited to, chemical vapor deposition (CVD), physical vapor deposition (PVD), atomic layer deposition (ALD), or any combination thereof, according to some implementations. Accordingly, first liner layer 318 may be filled in first lateral recess 314 and extended lateral recess 316. In some examples, when filling extended lateral recess 316, seams (shown as white in FIG. 3E) can be generated within first liner layer 318. In some examples, by virtue of first lateral recess 314 being thicker than the extended lateral recess 316, the occurrence of seams within first lateral recess 314 can be minimized or avoided.

At the subsequent processes, materials in extended lateral recess 316 can be removed and replaced with one or more conductive materials, rendering first liner layer 318 a sacrificial layer. As a result, first liner layer 318 can include any suitable sacrificial material. In some instances, first liner layer 318 may include at least one of polysilicon, a high-k dielectric material, carbon, or aluminum oxide.

Method 400 may continue at operation 410. A first portion of first liner layer 318 at the bottom of contact hole 310 may be removed to form a second lateral recess 320, as shown in FIG. 3F. In the same fabrication process, a second portion of first liner layer 318 over spacer layer 312 at the sidewalls of contact hole 310 may also be removed to expose spacer layer 312, according to some implementations. In some implementations, second lateral recess 320 may be identical or approximately identical to first lateral recess 314.

In the fabrication processes, the removal of the first portion of first liner layer 318 at the bottom of contact hole 310 may be controlled until an extent to remove part of first liner layer 318 in a lateral recess having the larger thickness H and leave another part of first liner layer 318 in another lateral recess having the smaller thickness h. Namely, the removal of first liner layer 318 may be stopped at a boundary between the thickness H and the thickness h. Accordingly, second lateral recess 320 in FIG. 3F may be identical or approximately identical to first lateral recess 314 in FIG. 3C. To form second lateral recess 320, wet etching and/or dry etching may be applied, through contact hole 310, to remove the desired amount of first liner layer 318, according to some implementations.

Method 400 may proceed to operation 412, in which a second liner layer 322 may be formed over exposed spacer layer 312 in contact hole 310 and in second lateral recess 320, as shown in FIG. 3G. According to some implementations, in the same fabrication process, second liner layer 322 may also be formed over initial stack structure 302. In some implementations, second liner layer 322 may be deposited using, but not limited to, chemical vapor deposition (CVD), physical vapor deposition (PVD), atomic layer deposition (ALD), or any combination thereof. At the subsequent processes, the lateral recesses are filled with one or more conductive materials, rendering both first liner layer 318 and second liner layer 322 sacrificial layers. As a result, first liner layer 318 can include a first sacrificial material, and second liner layer 322 can include a second sacrificial layer having a different removal (e.g., etching) selectivity from the first sacrificial material. For instance, first liner layer 318 may include a polysilicon layer, and second liner layer 322 may include a silicon nitride layer.

Subsequently, method 400 may proceed to operation 414. At operation 414, a contact filling material 324 may be formed to fill contact hole 310, as shown in FIG. 3H. In some implementations, contact filling material 324 may be formed over initial stack structure 302 in core array region 101 and connection region 103. Subsequently, contact filling material 324 may be patterned using lithography to leave part of contact filling material 324 within contact hole 310, and another part of contact filling material 324 outside contact hole 310 may be selectively removed, according to some implementations. In some implementations, in the same fabrication processes, second liner layer 322 over initial stack structure 302 may be removed together with contact filling material 324 over initial stack structure 302. In some examples, spacer layer 312 over initial stack structure 302 may be exposed after the removal. As a consequence, a sacrificial contact structure 326 can be created, as shown in FIG. 3H.

In the present disclosure, the term “sacrificial contact structure” used herein may refer to structure 326 including contact filling material 324, second liner layer 322 circumscribing contact filling material 324 and at the bottom of contact hole 310, and first liner layer 318 connecting second liner layer 322. According to some implementations, sacrificial contact structure 326 can be subsequently transformed into contact structure 102 by sequentially removing and replacing the materials in sacrificial contact structure 326.

In some implementations, the thickness of second liner layer 322 may be greater than the thickness of first liner layer 318, in the z-direction. In some implementations, first liner layer 318 can include a first sacrificial material, and second liner layer 322 can include a second sacrificial layer having a different removal (e.g., etching) selectivity from the first sacrificial material. For instance, first liner layer 318 may include a polysilicon layer, and second liner layer 322 may include a silicon nitride layer. Sacrificial contact structure 326 can serve as a foundation for the subsequent formation of contact structure 102 as depicted in FIG. 1B.

In FIG. 3H and other figures, although part of initial stack structure 302 (including first dielectric layer 124-1, second dielectric layer 128-1, and the other first dielectric layer 124-2) has been replaced and converted into part of sacrificial contact structure 326, for the simplification, the term “initial stack structure” and the reference numeral 302 are still used in these figures and in the description.

Returning to FIG. 2, as a consequence, sacrificial contact structures 326 as shown in FIG. 3H can be formed at operation 206.

Method 200 may proceed to operation 208. Operation 208 can be optional. In some implementations, when isolation structures 108 are to be formed (as shown in FIG. 1A), operation 208 can be performed. At operation 208, second dielectric layers 128 in part of initial stack structure 302 can be replaced by third dielectric layers 130 to transform the part of initial stack structure 302 to a dielectric stack structure 330 adjacent to isolation structure 108 formed later, as shown in FIG. 3I. Dielectric stack structure 330 can be located in the intermediate region between core array region 101 and connection region 103, according to some implementations. Dielectric stack structure 330 can be part of dielectric stack structure 114, in the intermediate region, shown in FIG. 1A. In some implementations in which no isolation structure 108 is arranged, operation 208 may be omitted. In some implementations, third dielectric layers 130 may be different from second dielectric layers 128. In some examples, second dielectric layers 128 can include silicon nitride layers, and third dielectric layers 130 can include silicon oxide.

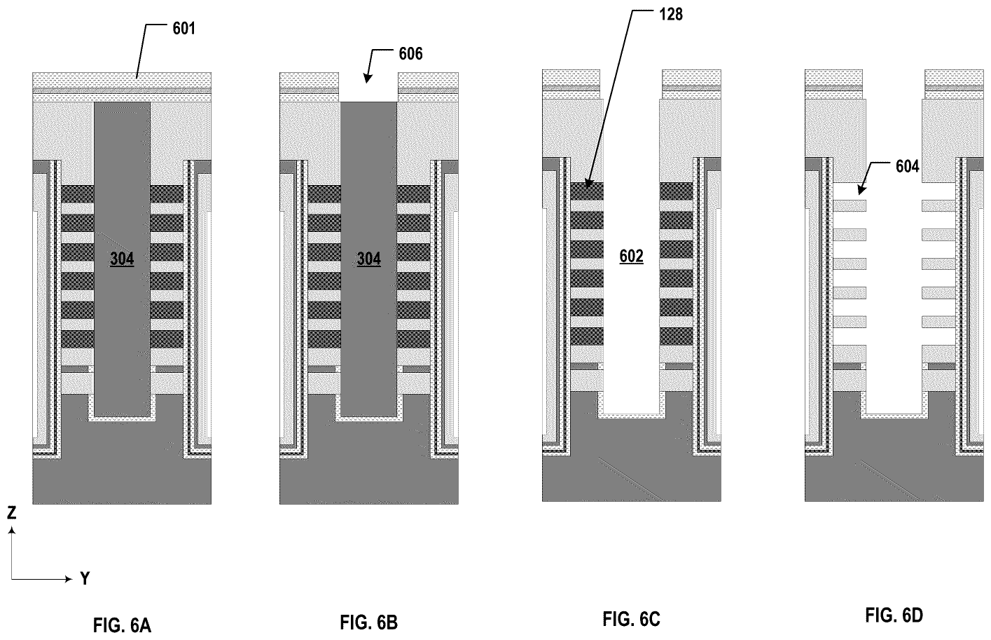

FIGS. 6A-6D illustrate the fabrication processes for replacing second dielectric layers 128, according to some aspects of the present disclosure. For simplification of the illustrations, each of FIGS. 6A-6D only depicts the intermediate region between core array region 101 and connection region 103, corresponding to a location where isolation structure 108 is to be formed. However, it can be understood that the operations depicted by FIGS. 6A-6D can be applied through any sacrificial filling structure 304, either in core array region 101 or in connection region 103, to replace second dielectric layers 128 in a gate replacement process.

To form a slit opening 602 and lateral recesses 604, a cap layer 601 may be formed over initial stack structure 302, as shown in FIG. 6A. Cap layer 601 can serve as a mask layer, according to some implementations. Subsequently, cap layer 601 can be patterned using lithography followed by wet etching and/or dry etching. As a consequence, part of cap layer 601 (and one or more layers below the part of cap layer 601) corresponding to sacrificial filling structure 304 may be selectively removed to form a trench 606, as shown in FIG. 6B. Based on trench 606, a sacrificial layer inside sacrificial filling structure 304 can be selectively removed (e.g., wet etching and/or dry etching) to form slit opening 602, as shown in FIG. 6C. For instance, potassium hydroxide (KOH) may be used for etching the sacrificial layer having polysilicon. Subsequently, through slit opening 602, corresponding second dielectric layers 128 can be removed to form lateral recesses 604, as shown in FIG. 6D.

Returning to FIG. 3I, through a slit opening 308 and lateral recesses as formed according to FIGS. 6A-6D, third dielectric layers 130 can be formed to replace part of second dielectric layers 128 in the lateral recesses and over the sidewalls of slit opening 308, as shown in FIG. 3I. As a consequence, dielectric stack structure 330 adjacent to isolation structure 108 can be formed, and dielectric stack structure 330 may include interleaved first dielectric layers 124 and third dielectric layers 130. In some examples, third dielectric layer 130 can also be formed over initial stack structure 302, e.g., on a cap layer, as shown in FIG. 3I, and can be removed in subsequence operations.

Returning to FIG. 2, at operation 210, second dielectric layers 128 of initial stack structure 302, corresponding to dummy channel structures 116, in connection region 103, and second dielectric layers 128 of initial stack structure 302, corresponding to channel structures 110, in core array region 101 may be respectively replaced with conductive layers, according to some implementations. Second dielectric layers 128 of initial stack structure 302, corresponding to dummy channel structures 116, in connection region 103 may be replaced with conductive layers 122 to form conductive stack structure 112 in connection region 103, as shown in FIG. 1A. On the other hand, second dielectric layers 128 of initial stack structure 302, corresponding to channel structures 110, in core array region 101, may be replaced with conductive layers 122 to form conductive stack structure 112 in core array region 101, as shown in FIG. 1A.

In some examples, second dielectric layers 128 of initial stack structure 302, corresponding to dummy channel structures 116, in connection region 103 may be removed. To remove second dielectric layers 128 in connection region 103, a slit opening 334 and lateral recesses 336 can be formed in connection region 103 and serve as passageways for subsequently filling the conductive layers in connection region 103 to replace second dielectric layers 128, as shown in FIG. 3J. The remaining second dielectric layers 128 adjacent to sacrificial contact structure 326 can form a dielectric stack structure 114.

The processes for forming slit opening 334 and lateral recesses 336 may be identical or similar to those depicted in FIGS. 6A-6D. For simplification of illustration and descriptions, details may be referred to the illustration and descriptions in regard to FIGS. 6A-6D. As shown in FIG. 3J, the removal of second dielectric layers 128 in connection region 103 may be performed to an extent, such that second dielectric layers 128 and first liner layer 318 surrounding sacrificial contact structures 326 remain intact. In some implementations, first liner layer 318 can serve as a stop layer during the removal processes.

Subsequently, first liner layer 318 can be further removed, using, e.g., a wet etching and/or a dry etching, according to some implementations. For instance, one or more wet etchants can be selected to remove first liner layer 318 and leave second liner layer 322 intact, as shown in FIG. 3K. The wet etchant for selectively removing first liner layer 318 can include any suitable wet etchant that has a relatively high selectivity (e.g., at least 20) between the material of first liner layer 318 and the material of second liner layer 322. In one example in which first liner layer 318 includes polysilicon, and second liner layer 322 includes silicon nitride, a wet etchant including, but not limited to, hydrofluoric acid (HF, e.g., buffered hydrofluoric acid (BHF)), may be applied to selectively remove first liner layer 318 without etching second liner layer 322. Namely, second liner layer 322 can serve as a stop layer to stop the wet etching when first liner layer 318 is removed to expose extended lateral recess 316, as shown in FIG. 3K.

FIG. 3L illustrates various cross-sectional side views in which slit opening 334 and lateral recesses 336, adjacent and corresponding to dummy channel structures 116, in connection region 103 can be filled with a third liner layer 338. Third liner layer 338 can function as a protection/stop layer to prevent, in a subsequent gate replacement process, second liner layer 322 in sacrificial contact structures 326 being removed.

In some implementations, third liner layers 338 may be comprehensively formed over a semiconductor structure 32, and filled in slit opening 334 and lateral recesses 336, as shown in FIG. 3L. When isolation structure 108 is to be formed, third liner layer 338 can be formed in slit opening 308. Subsequently, a removal process may be performed, using a chemical mechanical polishing (CMP) process, on the top surface of semiconductor structure 321 (shown in FIG. 3K having third liner layer 338 to form a semiconductor structure 323 having third liner layer 338 filled in slit opening 334 and lateral recesses 336 (and slit opening 308), as shown in FIG. 3L. In some examples, third liner layer 338 can extend laterally and fill in extended lateral recess 316, such that third liner layer 338 in extended lateral recess 316 can be in contact with second liner layer 322 in first lateral recess 314, as shown in FIG. 3L. At various levels, third liner layer 338 can extend laterally and fill in lateral recesses 336, such that third liner layer 338 in lateral recesses 316 (other than first lateral recess 314) can be in contact with second dielectric layers 128 in dielectric stack structure 114. In the same fabrication processes, one or more layers over the stack structure can also be removed together with third liner layer 338. Third liner layer 338 can be formed using one or more thin film deposition processes, such as CVD, PVD, ALD, or any combination thereof. Third liner layer 338 can include carbon, according to some implementations.

A gate replacement process in core array region 101 may be started. FIG. 3M illustrates various cross-sectional side views in which slit opening 340 and lateral recesses 342 may be formed using, e.g., a wet etching and/or a dry etching, according to some implementations. The fabrication processes for forming slit opening 340 and lateral recesses 342 may be identical or similar to those illustrated in FIGS. 6A-6D. Details may refer to the illustration and descriptions with respect to FIGS. 6A-6D. Slit opening 340 may first be formed and serve as a passageway. Second dielectric layers 128 in core array region 101 may then be removed through slit opening 340, thereby forming lateral recesses 342.

Subsequently, slit opening 334 and lateral recesses 336 in connection region 103 may be formed using, e.g., a wet etching and/or a dry etching, according to some implementations. The fabrication processes for forming slit opening 334 and lateral recesses 336 may be identical or similar to those illustrated in FIGS. 6A-6D. Details may refer to the illustration and descriptions with respect to FIGS. 6A-6D. Slit opening 334 may first be formed and serve as a passageway. Third liner layer 338 in connection region 103 may be removed through slit opening 334. In some implementations, third liner layer 338 in slit opening 308 in the intermediate region can also be removed during the same processes. In some implementations, third liner layer 338 may include a carbon layer, and the removal of the carbon layer can include a heat oxidization treatment to oxidize carbon into gaseous byproducts, thereby facilitating the removal of third liner layer 338. During the same processes, third liner layer 338 in extended lateral recess 316 can also be removed to expose extended lateral recess 316, as shown in FIG. 3N.

Returning to FIG. 2, at operation 210, the gate replacement process continues. Through slit opening 340 and slit opening 334, one or more conductive materials can be formed in lateral recesses 342 in core array region 101 and lateral recesses 336 in connection region 103, respectively, to form conductive layers 122 of conductive stack structure 112 in core array region 101 and connection region 103, as shown in FIG. 3O. In some implementations, high-k gate dielectric layers 126 may be formed before the formation of conductive layers 122, such that conductive layers 122 may be coated/covered with high-k gate dielectric layers 126 over the sidewalls of conductive layers 122, as shown in FIG. 3O.

In some implementations, conductive layers 122 in conductive stack structure 112 can include conductive materials including, but not limited to, tungsten (W), cobalt (Co), copper (Cu), aluminum (Al), titanium nitride (TiN), polycrystalline silicon (polysilicon), doped silicon, silicides, or any combination thereof. High-k gate dielectric layers 126 can include high-k dielectric materials, such as aluminum oxide (AlO), hafnium oxide (HfO), zirconium oxide (ZrO), or any combinations thereof, according to some implementations. In some examples, conductive layers 122 may include at least one of W or TiN.

Returning to FIG. 2, method 200 may proceed to operation 212. At operation 212, slit structures 106 can be formed, as shown in FIG. 3O. It can be understood that slit structure 106 may be an insulating structure. In other words, slit structure 106 may not include any contact (e.g., a source contact) and thus, does not introduce parasitic capacitance and leakage current with conductive layers 122. The present disclosure does not limit thereto.

In some implementations, slit structure 106 can include one or more conductive materials. For instance, slit openings 340 and 334 can be filled with, e.g., a polysilicon layer, respectively. In some implementations, a slit spacer 132 may be formed before the formation of the polysilicon layer, such that slit structures 106 as formed may include the polysilicon layer coated with slit spacer 132. Slit spacer 132 can be formed by depositing dielectrics into slit openings 340 and 334 using one or more thin film deposition processes, such as ALD, CVD, PVD, any other suitable processes, or any combination thereof. In some implementations, conductive materials (e.g., as a source contact; a polysilicon layer) can be deposited into slit openings 340 and 334 after the formation of slit spacer 132. The polysilicon layer can be formed into slit openings 340 and 334 and on a semiconductor structure 327 (shown in FIG. 3N), and an etching back process may be performed on the top surface of semiconductor structure 327. As a consequence, slit structures 106 as shown in FIGS. 1A and 1B can be formed.

Method 200 may proceed to operation 214, in which each sacrificial contact structure 326 may be further transformed into contact structures 102 in FIG. 1B. In some implementations, one or more cap layers 348 can be formed over a semiconductor structure 329 in FIG. 3O. Cap layers 348 can serve as mask layers. Cap layers 348 may include at least one of a silicon oxide layer or a silicon nitride layer. Subsequently, part of cap layers 348 corresponding to sacrificial contact structure 326 can be selectively removed, using, e.g., a wet etching and/or a dry etching, to expose contact filling material 324 in sacrificial contact structure 326, as shown in FIG. 3P. Contact filling material 324 in sacrificial contact structure 326 can be subsequently removed, as shown in FIG. 3Q. To expose first lateral recess 314 in a contact opening 350, second liner layer 322 (shown in FIG. 3Q) over the sidewalls and at the bottom of sacrificial contact structure 326 may be removed, as shown in FIG. 3R. In the same removal processes, high-k gate dielectric layer 126 coating a conductive layer 122-1 can also be removed. Upon high-k gate dielectric layer 126 being removed, the conductive material(s) in conductive layer 122-1 can be exposed.

It can be understood that high-k gate dielectric layer 126 can be uniformly formed over the conductive material(s) of conductive layers 122. With respect to FIGS. 3O to 3R and the figures in the following, in order to emphasize the existence of high-k gate dielectric layer 126, the thicknesses of part of high-k gate dielectric layer 126 may be enlarged.

Subsequently, a contact material 140 can be arranged over the sidewalls and at the bottom of contact opening 350 to fill first lateral recess 314, and a contact filler 144 can be filled in contact opening 350, as shown in FIG. 3S. In some implementations, contact material 140 may be coated with a glue layer 148. For instance, glue layer 148 can be formed before the formation of contact material 140, such that contact material 140 can be coated with a glue layer 148. As a consequence, exposed conductive layer 122-1 can be arranged in contact with glue layer 148, while high-k gate dielectric layer 126 can be arranged between the conductive material(s) of other conductive layers 122 and second dielectric layers 128 in dielectric stack structure 114 in connection region 103.

In some implementations, contact material 140 and contact filler 144 can be initially formed over certain regions of a semiconductor structure 335 (shown in FIG. 3R), and part of contact material 140 and contact filler 144 outside contact opening 350 can be selectively removed. In some implementations, contact material 140 may include, but not limited to, W, Co, Cu, Al, TiN, polysilicon, doped silicon, silicides, or any combination thereof. Contact filler 144 can include one or more dielectric materials, according to some implementations.

In some implementations, a contact pad 146 corresponding to contact structure 102 and DSG channel structures 134 corresponding to channel structures 110 may be formed, as shown in FIG. 3T. To form contact pad 146, one or more dielectric layers may be formed over a semiconductor structure 337 (shown in FIG. 3S). Subsequently, part of the one or more dielectric layers can be selectively removed to expose contact material 140 and channel structures 110, respectively. Accordingly, contact pad 146 and DSG channel structures 134 can be formed to be in contact with contact material 140 and channel structures 110, respectively.

As a consequence, a semiconductor structure 339 having contact structure 102 can be formed, as shown in FIG. 3T. FIG. 5B provides an enlarged cross-sectional side view 501 showing part of semiconductor structure 339 including contact structure 102, according to some aspects of the present disclosure. In some implementations, interconnect member 138 (including contact material 140 coated with glue layer 148) may include the thickness T, and first conductive layer 122-1 (including one or more conductive materials coated with high-k gate dielectric layer 126) may include the thickness t. The thickness T may be larger than the thickness t. In other words, T>t. In some examples, the difference between the thickness T and the thickness t is in the range of 2 nm to 6 nm. The ratio of the thickness t to the thickness T can be about 0.4 to about 0.85, according to some implementations. In some examples, a step g can be formed at one side (e.g., the top side) from the thickness t to the thickness T, as shown in FIG. 5B, and the thickness of step g may be in the range of 1 nm to 3 nm. In some implementations, the first interface may be arranged between interconnect member 138 and first conductive layer 122-1, and the second interface may be arranged between a second dielectric layer 128-1 and a second conductive layer 122-2. Second conductive layer 122-2 may be arranged above first conductive layer 122-1, and a first dielectric layer 124-1 may be arranged between first conductive layer 122-1 and second conductive layer 122-2 in the z-direction. As shown in FIG. 5B, in the cross-sectional view of contact structure 102, in the y-direction, the distance d from the sidewall of contact member 136 to the first interface is less than the distance D from the sidewall of contact member 136 to the second interface. In some implementations, in the y-direction, the distance d may be less than the third distance between the first interface and the second interface.

It is apparent that FIG. 3T may only show certain components/layers for the simplification of the illustrations. It can be understood that one or more components and/or one or more layers can be formed on the basis of semiconductor structure 339.

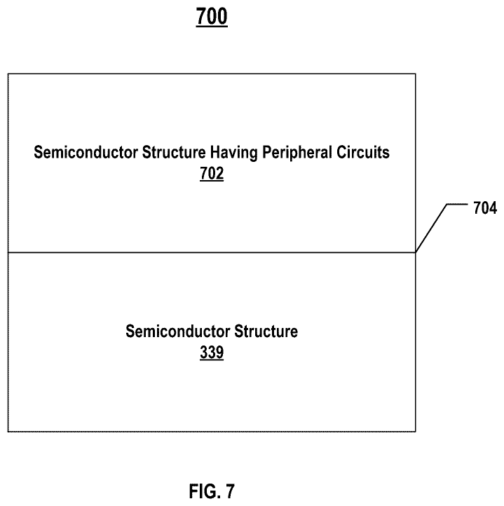

In some implementations, semiconductor structure 339 may be bonded with another semiconductor structure 702 having peripheral circuits through a bonding interface 704 to form a 3D memory device 700 later, as shown in FIG. 7. Memory cells of semiconductor structure 339 in the form of an array of NAND memory strings (i.e., channel structures 110) can be coupled with the peripheral circuits of semiconductor structure 702 through bonding interface 704. The peripheral circuits of semiconductor structure 702 may be configured to control the operations of the memory cells in semiconductor structure 339.

Subsequently, substrate 300 can be completely removed from the backside of a semiconductor structure 341 after the bonding (i.e., the bottom side in FIG. 3U). Semiconductor structure 341 may include the memory cells coupled with the peripheral circuits of semiconductor structure 702. In some implementations, substrate 300 can be completely removed using CMP, grinding, dry etching, and/or wet etching. In some implementations, substrate 300 may be peeled off. In some implementations in which substrate 300 may include silicon, substrate 300 may be removed using silicon CMP. In some implementations, substrate 300 (a silicon substrate) may be removed using wet etching by tetramethylammonium hydroxide (TMAH).

When/After removing substrate 300, a portion of memory film 352, in channel structure 110, including a storage layer, a blocking layer, and a tunneling layer that faces and is close to substrate 300 can be removed to expose the top portion of semiconductor channel 354 extending beyond stack structure 118. In some implementations, substrate 300 and the portion of memory film 352 can be removed by applying etchants on substrate 300. The etchants can include any suitable etchants that etch substrate 300 selective to semiconductor channel 354. Semiconductor channel 354 can extend further beyond stack structure 118 than the remaining memory film 352. In some examples, a portion of slit spacer 132 in slit structure 106 may also be removed such that a polysilicon layer 356 of slit structure 106 can be exposed. Subsequently, a semiconductor layer 358 can be formed to connect, e.g., semiconductor channels 354 and the polysilicon layer of slit structure 106. In some examples, one or more dielectric layers 360 may be formed over semiconductor layer 358. Subsequently, part of dielectric layer(s) 360 may be removed, and one or more conductor materials may be filled in to form contacts. Subsequently, 3D memory device 700 can be formed. However, it can be understood that the operations above merely provide an exemplary solution to connect channel structure 110, and the present disclosure does not limit thereto.

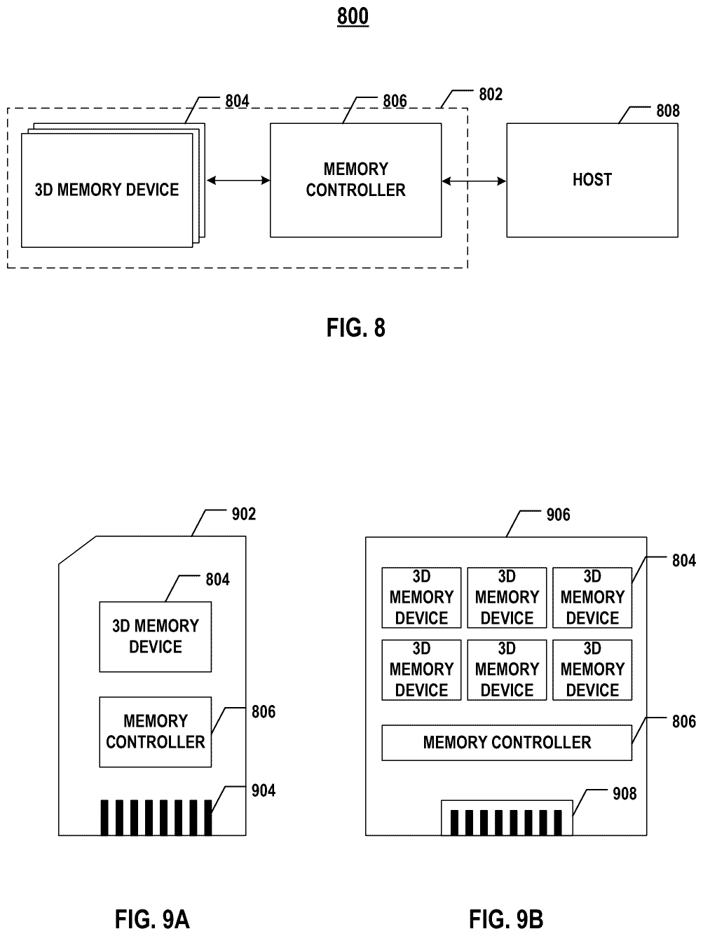

FIG. 8 illustrates a block diagram of an example system 800 having a 3D memory device, according to some aspects of the present disclosure. System 800 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 8, system 800 can include a host 808 and a memory system 802 having one or more 3D memory devices 804 and a memory controller 806. Host 808 can be a processor of an electronic device, such as a central processing unit (CPU), or a system-on-chip (SoC), such as an application processor (AP). Host 808 can be configured to send or receive data to or from 3D memory devices 804. 3D memory device 804 can be any 3D memory device disclosed herein, such as 3D memory device 700 depicted in FIG. 7.

Memory controller 806 (a.k.a., a controller circuit) is coupled to 3D memory device 804 and host 808 and is configured to control 3D memory device 804, according to some implementations. For instance, memory controller 806 may be configured to operate the plurality of channel structures via the word lines. Memory controller 806 can manage the data stored in 3D memory device 804 and communicate with host 808. In some implementations, memory controller 806 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 806 is designed for operating in a high duty-cycle environment SSDs or embedded multi-media-cards (eMMCs) used as data storage for mobile devices, such as smartphones, tablets, laptop computers, etc., and enterprise storage arrays. Memory controller 806 can be configured to control operations of 3D memory device 804, such as read, erase, and program operations. Memory controller 806 can also be configured to manage various functions with respect to the data stored or to be stored in 3D memory device 804 including, but not limited to bad-block management, garbage collection, logical-to-physical address conversion, wear leveling, etc. In some implementations, memory controller 806 is further configured to process error correction codes (ECCs) with respect to the data read from or written to 3D memory device 804. Any other suitable functions may be performed by memory controller 806 as well, for example, formatting 3D memory device 804. Memory controller 806 can communicate with an external device (e.g., host 808) according to a particular communication protocol. For example, memory controller 806 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 806 and one or more 3D memory devices 804 can be integrated into various types of storage devices, for example, be included in the same package, such as a universal Flash storage (UFS) package or an eMMC package. That is, memory system 802 can be implemented and packaged into different types of end electronic products. In one example as shown in FIG. 9A, memory controller 806 and a single 3D memory device 804 may be integrated into a memory card 902. Memory card 902 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 902 can further include a memory card connector 904 electrically coupling memory card 902 with a host (e.g., host 808 in FIG. 8). In another example as shown in FIG. 9B, memory controller 806 and multiple 3D memory devices 804 may be integrated into an SSD 906. SSD 906 can further include an SSD connector 908 electrically coupling SSD 906 with a host (e.g., host 808 in FIG. 8). In some implementations, the storage capacity and/or the operation speed of SSD 906 is greater than those of memory card 902.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described example implementations, but should be defined only in accordance with the following claims and their equivalents.

What is claimed is:

1. A memory device, comprising:
a stack structure comprising a first stack structure that comprises interleaved first dielectric layers and second dielectric layers, and a second stack structure that comprises interleaved first dielectric layers and conductive layers; and
a contact structure comprising a contact member extending, in a first direction, through the first stack structure and comprising an interconnect member extending in a second direction perpendicular to the first direction to connect with a first conductive layer extended from the second stack structure,
wherein:
the interconnect member is arranged at an end of the contact member and connected with the contact member; and
in the first direction, a thickness of the interconnect member is greater than a thickness of the first conductive layer extended from the second stack structure.

2. The memory device of claim 1, wherein:
a ratio of the thickness of the first conductive layer to the thickness of the interconnect member is about 0.4 to about 0.85.

3. The memory device of claim 1, wherein:
a first interface is arranged between the interconnect member and the first conductive layer, and a second interface is arranged between a second dielectric layer of the first stack structure and a second conductive layer of the second stack structure, the second conductive layer being arranged above the first conductive layer, and a first dielectric layer of the second stack structure being arranged between the first conductive layer and the second conductive layer in the first direction; and
in a cross-sectional view of the contact structure, in the second direction, a first distance from a sidewall of the contact member to the first interface is less than a second distance from the sidewall of the contact member to the second interface.

4. The memory device of claim 1, wherein:
the first conductive layer comprises a first conductive material covered with a high-k gate dielectric layer at top and bottom surfaces of the first conductive layer;
the interconnect member comprises a second conductive material coated with a glue layer at sidewalls of the interconnect member; and
the glue layer is sandwiched between the first conductive material and the second conductive material.

5. The memory device of claim 1, further comprising:
channel structures extending through part of the second stack structure in the first direction; and
in a cross-sectional view of the contact structure, each of the conductive layers, other than the first conductive layer, extends laterally to a region adjacent to the contact structure to be connected with a corresponding second dielectric layer of the first stack structure through which the contact structure extends.

6. The memory device of claim 1, further comprising dummy channel structures extending through part of the second stack structure, the part of the second stack structure being adjacent to the first stack structure through which the contact structure extends.

7. The memory device of claim 1, wherein:
the interconnect member is sandwiched between two first dielectric layers of the first stack structure in the first direction.

8. The memory device of claim 1, wherein the contact member comprises:
a contact spacer over a sidewall of the contact member;
a contact material over the contact spacer; and
a contact filler surrounded by the contact material.

9. The memory device of claim 1, further comprising:
slit structures each extending through the second stack structure in the first direction and laterally extending in a third direction, the third direction perpendicular to the first direction.

10. A system, comprising:
a memory device, comprising:
a stack structure comprising a first stack structure that comprises interleaved first dielectric layers and second dielectric layers, and a second stack structure that comprises interleaved first dielectric layers and conductive layers; and
a contact structure comprising a contact member extending through the first stack structure in a first direction and comprising an interconnect member extending in a second direction perpendicular to the first direction to connect with a first conductive layer extended from the second stack structure,
wherein:
the interconnect member is arranged at an end of the contact member and connected with the contact member; and
in the first direction, a thickness of the interconnect member is greater than a thickness of the first conductive layer extended from the second stack structure; and
a memory controller coupled to the memory device and configured to control an operation of the memory device.

11. A method of forming a semiconductor structure of a memory device, comprising:
forming a stack structure comprising a first stack structure that comprises interleaved first dielectric layers and second dielectric layers, and a second stack structure that comprises interleaved first dielectric layers and conductive layers; and
forming a contact structure comprising a contact member extending, in a first direction, through the first stack structure and comprising an interconnect member extending in a second direction perpendicular to the first direction to connect with a first conductive layer extended from the second stack structure,
wherein:
the interconnect member is arranged at an end of the contact member and connected with the contact member; and
in the first direction, a thickness of the interconnect member is greater than a thickness of the first conductive layer extended from the second stack structure.

12. The method of claim 11, wherein:
forming the stack structure comprises forming an initial stack structure comprising the interleaved first dielectric layers and second dielectric layers and arranged in a first region and a second region of the semiconductor structure, respectively;
forming the contact structure comprises forming a sacrificial contact structure extending, in the first direction, through the initial stack structure in the second region;
forming the stack structure further comprises replacing the second dielectric layers of a first portion of the initial stack structure with the conductive layers to form the second stack structure comprising an interleaved structure of the first dielectric layers and the conductive layers, the first stack structure comprising a second portion of the initial stack structure; and
forming the contact structure further comprises forming the contact structure based on the sacrificial contact structure, wherein the interconnect member extends in the second direction perpendicular to the first direction to connect with the first conductive layer extended from the second stack structure.

13. The method of claim 12, wherein forming the sacrificial contact structure in the second region comprises:
forming a first portion of the sacrificial contact structure extending, in the first portion, through the first stack structure in the second region;
forming a second portion of the sacrificial contact structure connected with the first portion of the sacrificial contact structure and extending laterally perpendicular to the first direction; and
forming a third portion of the sacrificial contact structure extended from the second portion of the sacrificial contact structure, a thickness of the second portion of the sacrificial contact structure, in the first direction, being greater than a thickness of the third portion of the sacrificial contact structure, and the second portion of the sacrificial contact structure comprising a first material different from a second material of the third portion of the sacrificial contact structure.

14. The method of claim 13, wherein forming the contact structure based on the sacrificial contact structure comprises:
replacing the second material of the third portion of the sacrificial contact structure, through a slit opening, with one or more conductive materials of the first conductive layer; and
replacing the first material of the second portion of the sacrificial contact structure, through a contact hole, with a contact material.

15. The method of claim 12, wherein forming the sacrificial contact structure extending through the first stack structure in the second region comprises:
forming a contact hole extending, in the first direction, through the first stack structure in the second region;
forming a first lateral recess at a bottom of the contact hole, the first lateral recess corresponding to a second dielectric layer of the first stack structure and corresponding to a top first dielectric layer and a bottom first dielectric layer, neighboring the second dielectric layer, of the first stack structure;
removing the corresponding second dielectric layer from the first lateral recess to form an extended lateral recess;
forming a first liner layer in the extended lateral recess; and
forming a second liner layer in the first lateral recess, the first liner layer being different from the second liner layer, and in the first direction.

16. The method of claim 15, wherein in the first direction, a thickness of the extended lateral recess is less than a thickness of the first lateral recess.

17. The method of claim 15, wherein:
a high-k gate dielectric layer is arranged between one or more conductive materials of a conductive layer of the second stack structure and a remaining second dielectric layer in the second region.

18. The method of claim 15, wherein:
a high-k gate dielectric layer is arranged between one or more conductive materials of the first conductive layer in the extended lateral recess and the second liner layer in the first lateral recess.

19. The method of claim 12, wherein:
the semiconductor structure is a first semiconductor structure; and
the method further comprises bonding the first semiconductor structure with a second semiconductor structure where peripheral circuits are formed.

20. The method of claim 19, wherein:
forming the first stack structure comprises forming the first stack structure over a substrate; and
the method further comprises:
forming channel structures extending through the second stack structure in the first region of the first semiconductor structure;
upon the first semiconductor structure being bonded with the second semiconductor structure, removing, from a side of the first semiconductor structure, the substrate and part of a memory film in each channel structure to expose a semiconductor channel of each channel structure; and
forming a semiconductor layer to connect the semiconductor channel of each channel structure.
